(19) United States
(12) Patent Application Publication
(10) Pub. No.: US 2024/0219493 A1
(43) Pub. Date: Jul. 4, 2024

(54) MAGNETIC RESONANCE DEVICES AND RADIO FREQUENCY DEVICES THEREOF

(71) Applicant: SHANGHAI UNITED IMAGING HEALTHCARE CO., LTD., Shanghai (CN)

(72) Inventors: Dashen CHU, Shanghai (CN); Shihao CHEN, Shanghai (CN); Shang XU, Shanghai (CN); Yunlei YAO, Shanghai (CN); Hai LU, Shanghai (CN)

(73) Assignee: SHANGHAI UNITED IMAGING HEALTHCARE CO., LTD., Shanghai (CN)

(21) Appl. No.: 18/401,266

(22) Filed: Dec. 29, 2023

(30) Foreign Application Priority Data
Dec. 29, 2022 (CN) 202211711224.4
Dec. 29, 2022 (CN) 202223544373.4
Dec. 30, 2022 (CN) 202211735075.5
Dec. 30, 2022 (CN) 202223595261.1

(51) Int. Cl. G01R 33/3415; G01R 33/34; G01R 33/36

(52) U.S. Cl. CPC G01R 33/3415; G01R 33/34084; G01R 33/3621

(57) ABSTRACT

Embodiments of the present disclosure provide a radio frequency device and a magnetic resonance device. The radio frequency device may include a surface coil including at least one coil assembly. The at least one coil assembly may include a first coil assembly and a second coil assembly. The first coil assembly may include at least two first coil units arranged in an array. The second coil assembly may include at least one second coil unit. The first coil assembly and the second coil assembly may be arranged in a stacked configuration.

### CROSS-REFERENCE TO RELATED APPLICATIONS

This application claims priority to the Chinese Patent Application No. 202211711224.4 filed on Dec. 29, 2022, the Chinese Patent Application No. 202223544373.4 filed on Dec. 29, 2022, the Chinese Patent Application No. 202211735075.5, filed on Dec. 30, 2022, and the Chinese Patent Application No. 202223595261.1, filed on Dec. 30, 2022, the entire contents of each of which are hereby incorporated by reference.

### TECHNICAL FIELD

The present disclosure relates to magnetic resonance technique, and in particular, to a radio frequency device and a magnetic resonance device.

### BACKGROUND

A radio frequency device may implement radio frequency excitation and receive a magnetic resonance signal during a magnetic resonance imaging (MRI) scanning. A radio frequency device may include a surface coil, such as an ultra-flexible coil. With high signal-to-noise ratios and high parallel imaging capabilities, multiple coil arrays can be used simultaneously to meet varying clinical needs (e.g., workload, improvement in coverage area, etc.), thus widely used in magnetic resonance imaging.

### SUMMARY

One of the embodiments of the present disclosure provides a radio frequency device. The radio frequency device may include a surface coil, and the surface coil may include at least one coil assembly. The at least one coil assembly may include a first coil assembly and a second coil assembly. The first coil assembly may include at least two first coil units arranged in an array. The second coil assembly may include at least one second coil unit. The first coil assembly and the second coil assembly may be arranged in a stacked configuration.

In some embodiments, a projection of a center of each of the at least one second coil unit on the first coil assembly along a stacked direction may have a distance from a center of each of the at least two first coil units.

In some embodiments, the projection of the center of each of the at least one second coil unit on the first coil assembly along the stacked direction may be located between centers of adjacent first coil units of the at least two first coil units.

In some embodiments, the projection of the center of each of the at least one second coil unit on the first coil assembly along the stacked direction may be located at a midpoint of a line connecting the centers of the adjacent first coil units.

In some embodiments, the at least two first coil units of the first coil assembly may be partially overlapped to form one or more overlapped regions, and the projection of the center of each of the at least one second coil unit on the first coil assembly along the stacked direction may be located in one of the one or more overlapped regions.

In some embodiments, the projection of the center of each of the at least one second coil unit on the first coil assembly along the stacked direction may be located at a center of the one of the one or more overlapped regions.

In some embodiments, the projection of the center of each of the at least one second coil unit on the first coil assembly along the stacked direction may be located at a first overlapped region of adjacent first coil units arranged along a first direction. The projection of the center of each of the at least one second coil unit on the first coil assembly along the stacked direction may be located in a second overlapped region of the adjacent first coil units arranged along a second direction. At least four first coil units may be arranged in an array along the first direction and the second direction of the adjacent first coil units, the four first coil units may have a third overlapped region, and the projection of the center of each of the at least one second coil unit on the first coil assembly along the stacked direction may be located in the third overlapped region.

In some embodiments, the second coil assembly may include at least two second coil units arranged in an array.

In some embodiments, the surface coil may have one or more through holes along a thickness direction of the surface coil.

In some embodiments, the surface coil may be configured to have a first surface coil, the first surface coil may include the first coil assembly and the second coil assembly. The first surface coil may further include a first cladding layer, and the first coil assembly and the second coil assembly may both be encased within the first cladding layer. The one or more through holes may include a first hollow hole provided on the first cladding layer.

In some embodiments, the surface coil may be configured to have a second surface coil and a third surface coil. The second surface coil may include the first coil assembly. The third surface coil may include the second coil assembly. The second surface coil may be detachably connected with the third surface coil.

In some embodiments, the second surface coil further may include a second cladding layer, and the second cladding layer may encase the first coil assembly. The third surface coil further may include a third cladding layer, and the third cladding layer may encase the second coil assembly. The second cladding layer may be detachably connected with the third cladding layer.

In some embodiments, the one or more through holes may include a plurality of second hollow holes provided on the second cladding layer and a plurality of third hollow holes provided on the third cladding layer. Positions of the plurality of second hollow holes may correspond to a position of a portion of the third cladding layer. Positions of the plurality of third hollow holes may correspond to a position of a portion of the second cladding layer.

In some embodiments, the radio frequency device may further include an arrangement layer, a fourth cladding layer, and a sealing structure. The arrangement layer and the fourth cladding layer may be flexible, at least one of the first coil assembly and the second coil assembly may be provided on the arrangement layer, and the fourth cladding layer may be provided on the arrangement layer and covers at least one of the first coil assembly and the second coil assembly. The one or more through holes may form a hollow structure. The sealing structure may be provided along an edge of the hollow structure, and the sealing structure may include a sealing portion, a bonding region, and a stitching portion. The bonding region may wrap around outside the edge of the hollow structure and bond the fourth cladding layer and the arrangement layer. The sealing portion may be provided along an inner edge of the bonding region and may be sealed to the fourth cladding layer and the arrangement layer. The stitching portion may be provided along an outer edge of the bonding region and stitch the fourth cladding layer and the arrangement layer.

In some embodiments, a first hole may be provided in the arrangement layer. One or more second holes may be provided on the fourth cladding layer at a position corresponding to the first hole. The sealing structure may be provided along an edge of the first hole and an edge of the second hole. The fourth cladding layer may include a top layer and a bottom layer, the top layer may be provided on a top surface of the arrangement layer, the bottom layer may be provided on a bottom surface of the arrangement layer, and the at least one of the first coil assembly and the second coil assembly may be provided on the top surface of the arrangement layer. The one or more second holes may be provided on the top layer and the bottom layer at corresponding positions, the sealing structure may be provided along an edge of the first hole, an edge of the second hole on the top layer, and an edge of the second hole on the bottom layer. The bottom layer may include an annular region formed around the sealing structure. In the annular region, a distance between the bottom layer and the arrangement layer in the thickness direction of the surface coil may decrease from an outer side of the annular region towards an inner side of the annular region.

In some embodiments, the radio frequency device may further include an arrangement layer, a fourth cladding layer, and a plurality of sealing structures. The arrangement layer and the fourth cladding layer may be flexible, the at least one coil assembly may be provided on the arrangement layer, and the fourth cladding layer may be provided on the arrangement layer and covers the at least one coil assembly. The plurality of hollow structures may be formed through the surface coil along a thickness direction of the surface coil. The plurality of the sealing structures may be provided in one-to-one correspondence with the plurality of hollow structures.

In some embodiments, the surface coil may further include a transmission line and a preamplifier, and the preamplifier may be provided separately from the at least one coil assembly.

The at least one coil assembly may include a flexible conductive wire, and the flexible conductive wire may surround to form at least one coil unit for receiving a magnetic resonance signal. The flexible conductive wire may include a transmission segment for tuning. The transmission line may be configured to realize an impedance matching between the coil unit and the preamplifier. The preamplifier may be configured to amplify the magnetic resonance signal received by the at least one coil assembly. One end of the transmission line may be connected with an output end of the flexible conductive wire, and another end of the transmission line, may extend outside of the at least one coil assembly and be connected with the preamplifier.

In some embodiments, the radio frequency device may be applied in a magnetic resonance device.

One of the embodiments of the present disclosure provides a radio frequency device. The radio frequency device may include a surface coil. The surface coil may include at least one coil assembly. The at least one coil assembly may include a first coil assembly and a second coil assembly. The first coil assembly may include at least two first coil units arranged in an array, and the second coil assembly may include at least one second coil unit. The at least one second coil unit and the at least two first coil unit may be physically separated from each other and may be arranged staggered up and down.

One of the embodiments of the present disclosure provides a radio frequency device. The radio frequency device may include a first surface coil including at least one first coil assembly and a first cladding layer, the first cladding layer encasing the at least one first coil assembly. The radio frequency device may also include a second surface coil including at least one second coil assembly and a second cladding layer, the second cladding layer encasing the at least one second coil assembly. The first cladding layer may be detachably connected with the second cladding layer.

### BRIEF DESCRIPTION OF THE DRAWINGS

The present disclosure is further illustrated in terms of exemplary embodiments. These exemplary embodiments are described in detail with reference to the drawings. These embodiments are non-limiting exemplary embodiments, in which like reference numerals represent similar structures, wherein:

FIG. 1-FIG. 4, FIG. 5C, FIG. 6C, FIG. 7C, FIG. 8C, FIG. 9, and FIG. 10 are schematic diagrams illustrating exemplary surface coils according to some embodiments of the present disclosure;

FIG. 5A, FIG. 6A, FIG. 7A, and FIG. 8A are schematic diagrams illustrating exemplary structures of a first coil assembly according to some embodiments of the present disclosure;

FIG. 5B, FIG. 6B, FIG. 7B, and FIG. 8B are schematic diagrams illustrating exemplary structures of a second coil assembly according to some embodiments of the present disclosure;

FIG. 11 is a schematic diagram illustrating an exemplary first surface coils according to some other embodiments of the present disclosure;

FIG. 12 is a schematic diagram illustrating an exemplary second surface coils according to some embodiments of the present disclosure;

FIG. 13 is a schematic diagram illustrating an exemplary third surface coils according to some other embodiments of the present disclosure;

FIG. 14, FIG. 15, and FIG. 16 are schematic diagrams illustrating exemplary surface coils according to some embodiments of the present disclosure;

FIG. 17 is a schematic diagram illustrating an exemplary radio frequency device according to some embodiments of the present disclosure;

FIG. 18 is a schematic diagram illustrating an exemplary arrangement layer, a hollow structure, and a coil assembly of a radio frequency device according to some embodiments of the present disclosure;

FIG. 19 is a schematic diagram illustrating an exemplary part A of a radio frequency device in FIG. 17;

FIG. 20 is a diagram illustrating a B-B cross-sectional view of part A of a radio frequency device in FIG. 19;

FIG. 21 is a diagram illustrating a cross-sectional view of a partial region of a radio frequency device according to some embodiments of the present disclosure;

FIG. 22 is a schematic diagram illustrating an exemplary stacked configuration of a first coil assembly and a second coil assembly of a radio frequency device according to some other embodiments of the present disclosure;

FIG. 23 is a diagram illustrating a cross-sectional view of a partial region of a radio frequency device according to some other embodiments of the present disclosure;

FIG. 24 is a schematic diagram illustrating an exemplary circuit structure of a surface coil according to some embodiments of the present disclosure;

FIG. 25A is a schematic diagram illustrating an exemplary detuning process of a surface coil according to some embodiments of the present disclosure; and

FIG. 25B is a schematic diagram illustrating an exemplary passively detuned surface coil according to some embodiments of the present disclosure.

In the figure, 1000 is a radio frequency device, 100 is a surface coil, 110 is a first coil assembly, 111 is a first coil unit, 111-1 is a first coil unit one, 111-2 is a first coil unit two, 120 is a second coil assembly, 121 is the second coil unit, 130 is the coil assembly, 131 is a coil unit, 132 is a flexible conductive wire, 132-1 is core wires, 132-2 is ground wires, 132-3 is a transmission segment, 133 is a transmission line, 134 is a preamplifier, 140 is an arrangement layer, 150 is a fourth cladding layer, 151 is a top layer, 152 is a bottom layer, 153 is an annular region, 160 is a hollow structure, 161 is a first hole, 162 is a second hole, 170 is a sealing structure, 171 is a sealing portion, 172 is a bonding region, 173 is a stitching portion, 180 is a flexible filler, 190 is a hole, 200 is a first surface coil, 210 is a first cladding layer, 220 is a first hollow hole, 300 is a second surface coil, 310 is a second cladding layer, 320 is a second hollow hole, 400 is a third surface coil, 410 is a third cladding layer, and 420 is a third hollow hole.

### DETAILED DESCRIPTION

To more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation. Unless obviously obtained from the context or the context illustrates otherwise, the same numeral in the drawings refers to the same structure or operation.

It should be understood that “system”, “device”, “unit” and/or “module” as used herein is a manner used to distinguish different components, elements, parts, sections, or assemblies at different levels. However, if other words serve the same purpose, the words may be replaced by other expressions.

As shown in the present disclosure and the claims, unless the context clearly suggests exceptional circumstances, the words “a”, “an” and/or “the” do not specifically refer to the singular but may also include the plural. In general, the terms “comprise,” “comprises,” “comprising,” “include,” “includes,” and/or “including,” merely prompt to include operations and elements that have been clearly identified, and these operations and elements do not constitute an exclusive listing.

The flowcharts used in the present disclosure illustrate operations that systems implement according to some embodiments of the present disclosure. It should be understood that the previous or subsequent operations may not be accurately implemented in order. Instead, each step may be processed in reverse order or simultaneously. Meanwhile, other operations may also be added to these processes, or a certain step or several steps may be removed from these processes.

As a count of channels supported by a system spectrometer increases, a size of a surface coil unit that makes up the multi-channel surface arrays is typically reduced. However, a small-sized surface coil unit has a relatively low depth signal-to-noise ratio and poor acceleration in an anterior-posterior direction (also referred to as AP direction), resulting in lower image quality. Therefore, it is desired to provide a radio frequency device that may enhance the depth signal-to-noise ratio and parallel imaging capability in the AP direction to further improve image quality.

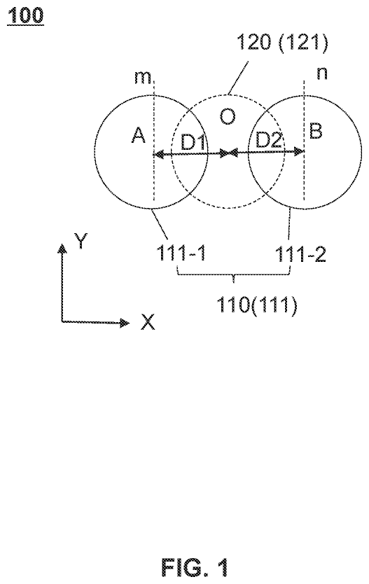

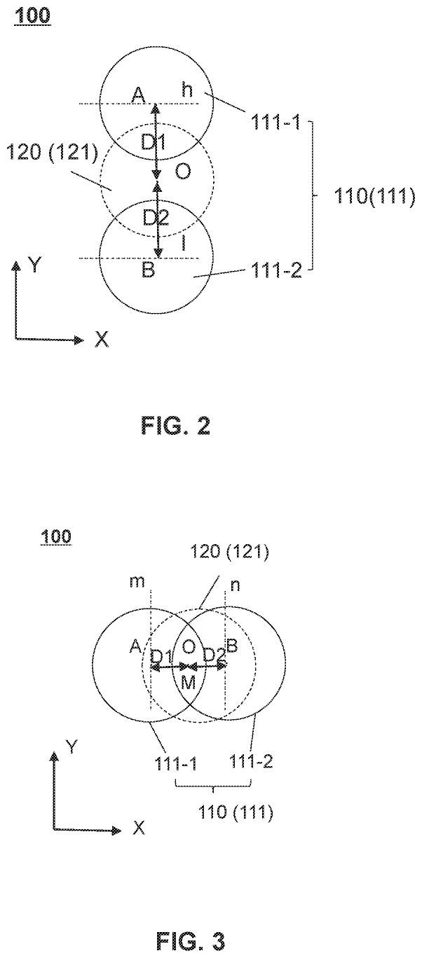

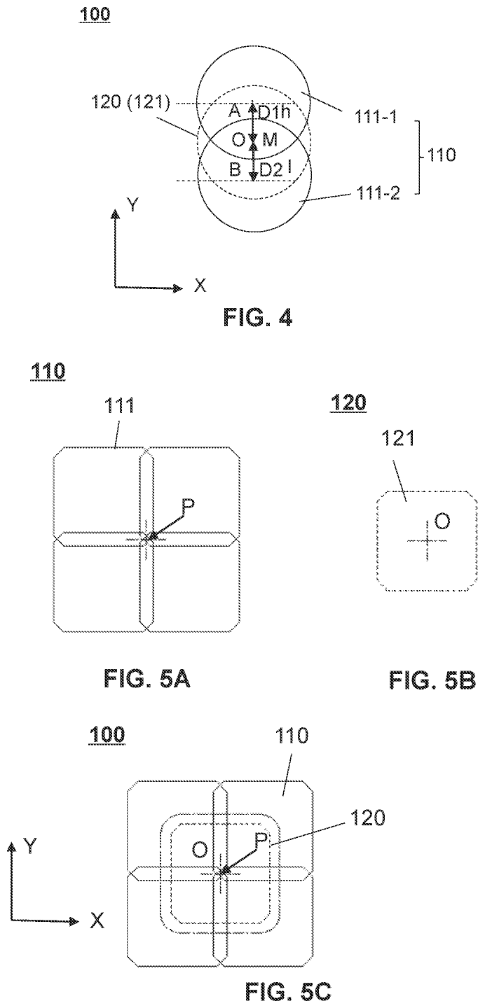

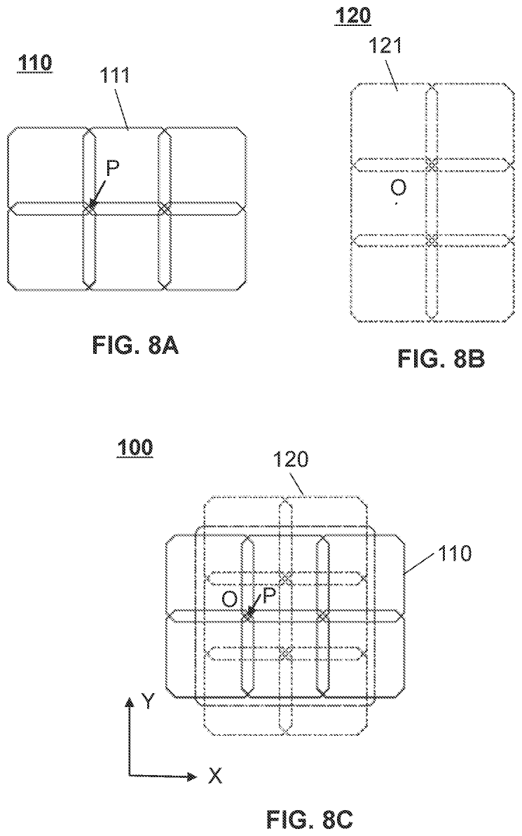

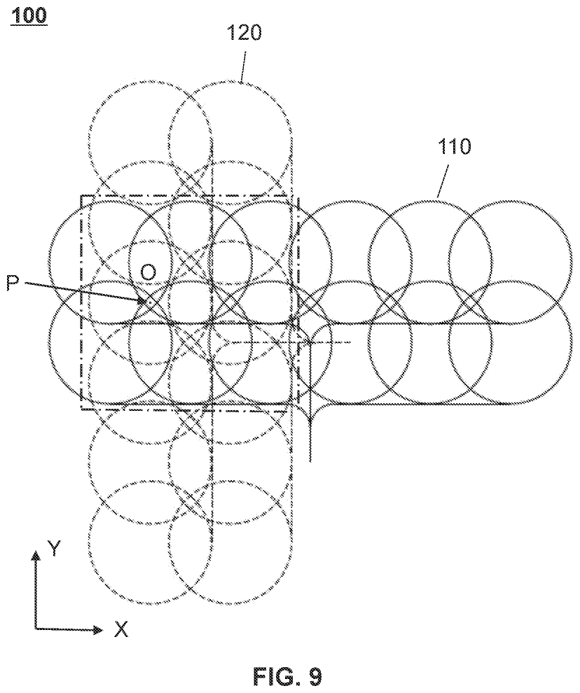

The radio frequency device may implement radio frequency excitation and receive a magnetic resonance signal. In some embodiments, as shown in FIG. 1-FIG. 4, FIG. 5C, FIG. 6C, FIG. 7C, FIG. 8C, FIG. 9, and FIG. 10, the radio frequency device 1000 may include a surface coil 100 for transmitting and/or receiving a magnetic resonance signal. The surface coil 100 may include a first coil assembly 110 and a second coil assembly 120. For the purpose of clearly representing an arrangement of the first coil assembly 110 and the second coil assembly 120, merely by way of example, FIG. 1-FIG. 4, FIG. 5A-FIG. 5C, FIG. 6A-FIG. 6C, FIG. 7A-FIG. 7C, FIG. 8A-FIG. 8C, FIG. 9, FIG. 10, FIG. 13, FIG. 14, and FIG. 15 are shown with solid lines representing the first coil assembly and dashed lines representing the second coil assembly.

The radio frequency device may include a surface coil and the surface coil may include at least one coil assembly. A coil assembly may implement RF excitation and receive an MRI signal during an MRI scanning. In some embodiments, a plurality of coil assemblies may be used in combination. In some embodiments, different coil assemblies may all be wrapped around a human's body (e.g., the plurality of coil assemblies are arranged side-by-side) to achieve coverage of a larger area of the ‘human's body. However, such a combined usage of coil assemblies may not improve the signal-to-noise ratio and the parallel imaging capability of the radio frequency device.

Embodiments of the present disclosure provide the radio frequency device. The surface coil may include the first coil assembly and the second coil assembly which may operate independently. In some embodiments, the surface coil may include a first surface coil, and the first coil assembly and the second coil assembly may be provided on the first surface coil. At this time, the first coil assembly and the second coil assembly may be used in combination. During the manufacturing process of the radio frequency device, a relative position between the first coil assembly and the second coil assembly may be determined in a manner described in the following embodiments, and then the relative position may be fixed (e.g., fixed in a first cladding layer) and the surface coil may be produced. In some embodiments, the surface coil may include a second surface coil and a third surface coil. The first coil assembly may be provided on the second surface coil, and the second coil assembly may be provided on the third surface coil. At this time, the first coil assembly and the second coil assembly may be used independently or in combination according to imaging needs of subjects (e.g., a human's body). When the first coil assembly and the second coil assembly are used in combination, the second surface coil may be detachably connected with the third surface coil. Thus, at least a portion of at least two first coil units of the first coil assembly and at least one second coil unit of the second coil assembly may be arranged in a stacked configuration. Such configuration ensures a stable connection between the first coil assembly and the second coil assembly when used in combination, thereby ensuring stable imaging. Additionally, a stacked arrangement allows for a higher signal-to-noise ratio and improved parallel imaging capability in a stacked region. When the radio frequency device is operating, the relative position between the first coil assembly and the second coil assembly may be determined in the manner described in the following embodiments, and then the relative position may be fixed through a mechanical connection structure (e.g., a detachable connection structure).

FIG. 1-FIG. 4, FIG. 5C, FIG. 6C, FIG. 7C, FIG. 8C, FIG. 9, and FIG. 10 are schematic diagrams illustrating exemplary surface coils according to some embodiments of the present disclosure. FIG. 5A, FIG. 6A, FIG. 7A, and FIG. 8A are schematic diagrams illustrating exemplary structures of a first coil assembly according to some embodiments of the present disclosure. FIG. 5B, FIG. 6B, FIG. 7B, and FIG. 8B are schematic diagrams illustrating exemplary structures of a second coil assembly according to some embodiments of the present disclosure.

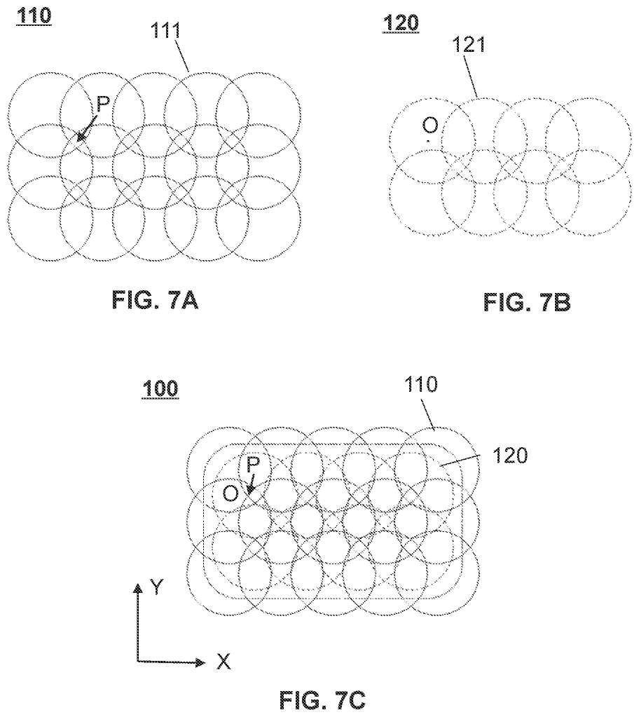

In some embodiments, the surface coil 100 may include a first coil assembly 110 and a second coil assembly 120. The first coil assembly 110 may include at least two first coil units 111 arranged in an array, and the second coil assembly 120 may include at least one second coil unit 121. The first coil assembly 110 and the second coil assembly 120 may be arranged in a stacked configuration. The radio frequency device may include one surface coil or a plurality of surface coils. For example, as shown in FIG. 12 and FIG. 13, the radio frequency device has a second surface coil 300 and a third surface coil 400.

In some embodiments, the first coil unit 111 may be in a regular or irregular shape, such as a torus, a circle, a square, a hexagon, an octagon, a butterfly, a saddle, etc. The at least two first coil units 111 arranged in an array may be in the same plane or approximately the same plane. In some embodiments, the at least two first coil units 111 may be arranged in a rectangular array (also referred to as a matrix, i.e., extending in two mutually perpendicular directions, such as a first direction and a second direction as described below). The matrix may be represented as an m (row)*n (column) matrix, where m denotes an integer greater than 0 and n denotes an integer greater than 1, or m denotes an integer greater than 1 and n denotes an integer greater than 0. For example, as shown in FIG. 1 and FIG. 3, the first coil assembly 110 may include a first coil unit 111-1 and a first coil unit 111-2, which may be arranged in a 1*2 matrix. As another example, as shown in FIG. 2 and FIG. 4, the first coil assembly 110 may include the first coil unit 111-1 and the first coil unit 111-2, which may be arranged in a 2*1 matrix. As another example, as shown in FIG. 5A, the first coil assembly 110 may be arranged in a 2*2 matrix. As still another example, as shown in FIG. 6A, the first coil assembly 110 may be arranged in a 3*3 matrix. As still another example, as shown in FIG. 7A, the first coil assembly 110 may be arranged in a 3*5 matrix. As still another example, as shown in FIG. 8A, the first coil assembly 110 may be arranged in a 2*3 matrix. As still another example, as shown in FIG. 9 and FIG. 10, the first coil assembly 110 may be arranged in a 2*6 matrix. In some embodiments, the at least two first coil units 111 may be arranged in an irregular array. The at least two first coil units 111 may be of the same or different shapes. The at least two first coil units 111 may be of the same or different sizes. For example, first coil units in an edge region of the first coil assembly may have a larger size than first coil units in a non-edge region of the first coil assembly. That is, the size of a first coil unit in the edge region of the first coil assembly 110 may be larger than the size of a first coil unit in a middle region of the first coil assembly 110, which facilitates the formation of a non-equal density multi-channel coil. The following description mainly takes an example of the at least two first coil units 111 being arranged in a rectangular array.

In some embodiments, the second coil unit 121 may be in regular or irregular shape, such as a ring, a circle, a square, a hexagon, an octagon, a butterfly, a saddle, etc. In some embodiments, the second coil assembly 120 may include at least one second coil unit 121. For example, as shown in FIG. 1-FIG. 4, and FIG. 5B, the second coil assembly 120 may include only one second coil unit 121. In some embodiments, the second coil assembly 120 may include at least two second coil units 121. In some embodiments, when a count of second coil units 121 is greater than 1, the at least two second coil units 121 may be arranged in an array, e.g., in a matrix, a circular array, etc. For example, as shown in FIG. 6B, the second coil assembly 120 may be arranged in a 3*3 matrix. As another example, as shown in FIG. 7B, the second coil assembly 120 may be arranged in a 2*4 matrix. As still another example, as shown in FIG. 8B, the second coil assembly 120 may be arranged in a 3*2 matrix. As still another example, as shown in FIG. 9, the second coil assembly 120 may be arranged in a 6*2 matrix. As still another example, as shown in FIG. 10, the second coil assembly 120 may be arranged in a 2*6 matrix. In some embodiments, at least two of the at least two second coil units 121 may be of the same or different shapes. At least two of the at least two second coil units 121 may be of the same or different sizes. For example, a size of the second coil unit in an edge region of the second coil assembly 120 may be larger than a size of the second coil unit in a middle region of the second coil assembly 120, which facilitates the formation of non-equal density multi-channel coils. In some other embodiments, the at least two second coil units 121 may be arranged in a non-array. For example, the at least two second coil units 121 may be arranged irregularly.

In some embodiments, the count of the first coil units 111 in the first coil assembly 110 may be the same or different from the count of the second coil units 121 in the second coil assembly 120. In some embodiments, the shape of the first coil unit in the first coil assembly 110 may be the same or different from the shape of the second coil unit in the second coil assembly 120. In some embodiments, the size of the first coil unit in the first coil assembly 110 may be the same or different from the size of the second coil unit in the second coil assembly 120. In some embodiments, the arrangement of the first coil units 111 in the first coil assembly 110 may be the same or different from the arrangement of the second coil units 121 in the second coil assembly 120. In some embodiments, at least one of the first coil assembly 110 and/or the second coil assembly 120 may be formed by a flexible conductive wire. The flexible conductive wire may be a twisted pair wire, a microstrip wire, a coaxial wire, etc. At least one of the first coil assembly 110 or the second coil assembly 120 may use fabric as a carrier, and the fabric may be made of a deformable material in a yarn form, such as silk, cotton, fur, textile fiber, polyester, etc.

In some embodiments, the count, shape, size, and arrangement of at least one of the first coil units 111 in the first coil assembly 110 and the second coil unit 121 in the second coil assembly 120 may be determined based on a clinical need (e.g., relevant information about a region of interest) without being affected by a count of surface coil channels (e.g., reducing the size of coil units in order to increase the count of surface coil channels). Accordingly, embodiments of the present disclosure may determine the size of the coil units (e.g., the first coil units 111, the second coil unit 121) based on the clinical need, and further may increase the penetration depth of a signal-to-noise ratio of the surface coil. In some embodiments, relevant information about the region of interest may include a position, size, etc. of the region of interest.

In some embodiments, the first coil assembly 110 and the second coil assembly 120 may be arranged in a stacked configuration, which may improve parallel imaging capability of an AP direction with the other encoding directions (e.g., an up-to-down direction, a left-to-right direction), thereby obtaining images with better quality in fast imaging in the AP direction. In some embodiments, the stacked configuration refers to a plane in which the first coil assembly 110 is located is parallel or approximately parallel to a plane in which the second coil assembly 120 is located. At least one second coil unit in the second coil assembly 120 may be at least partially overlapped with each of at least two of the first coil units in the first coil assembly 110. At this time, the first coil assembly 110 and the second coil assembly 120 may be understood to be stacked in a stacked direction. In some embodiments, partially overlapped refers to a portion of a projection of the at least one second coil unit in the second coil assembly 120 along the stacked direction on a plane being covered by a portion of a projection of each of the at least two first coil units in the first coil assembly 110 along the stacked direction on the same plane or covered by the at least two first coil units in the first coil assembly 110. For example, as shown in FIG. 1-FIG. 4, the second coil assembly 120 may be arranged above or below the first coil assembly 110, and the projection of the second coil unit 121 along the stacked direction on the first coil assembly 110 partially overlaps with the projection of each of the first coil unit 111-1 and the first coil unit 111-2 along the stacked direction. As another example, as shown in FIG. 5C and FIG. 7C, a projection of the second coil assembly 120 along the stacked direction on the first coil assembly 110 is located within a region covered by the first coil assembly 110. As another example, as shown in FIG. 6C and FIG. 8C, the projection of the second coil assembly 120 along the stacked direction and the first coil assembly 110 are partially overlapped.

In some embodiments, the first coil assembly 110 may be physically isolated from the second coil unit 121 when the first coil assembly 110 is arranged in a stacked configuration with the second coil assembly 120 to avoid a short circuit. For example, the first coil unit 111-1, the first coil unit 111-2, and/or the second coil unit 121 may be provided with an insulating layer around a periphery. As another example, when the second coil assembly 120 is stacked above the first coil assembly 110, an overlapping portion of the second coil assembly 120 and the first coil assembly 110 may be provided with an embossment to avoid contacting between the second coil assembly 120 with the first coil assembly 110. The embossment may be provided on the second coil assembly 120 and/or the first coil assembly 110. For example, the embossment may be provided on the second coil unit 121 at the overlapping portion of the second coil unit 121 with the first coil unit 111-1 or the first coil unit 111-2. As another example, the embossment may be provided on the first coil unit 111-1 or the first coil unit 111-2 at the overlapping portion of the first coil unit 111-1 or the first coil unit 111-2 with the second coil unit 121.

In some embodiments, the stacked direction refers to a direction perpendicular to the plane in which the second coil unit 121 or the second coil assembly 120 is located, which is also referred to as an axial direction of the second coil unit or an axial direction of the second coil assembly. For example, as shown in FIGS. 1-4, FIG. 5C, FIG. 6C, FIG. 7C, FIG. 8C, FIG. 9, and FIG. 10, the plane in which the second coil unit 121 or the second coil assembly 120 is located is an XY plane or a plane parallel to the XY plane, and the stacked direction may be a direction perpendicular to the XY plane. It may be understood that the XY plane refers to a plane in which an X direction (also referred to as the first direction) and a Y direction (also referred to as the second direction) are located. Furthermore, it may be understood that, in order to illustrate a relative positional relationship between the first coil assembly 110 and the second coil assembly 120, an arrangement manner of each of the first coil units 111, and an arrangement manner of each of the at least one second coil unit 121, the present disclosure is illustrated with an example that both the first coil units 111 and the second coil unit 121 are arranged on a plane, and the stacked direction may also be referred to as a vertical direction. However, when the radio frequency device 1000 is operating, a part or all of the first coil assembly 110 and the second coil assembly 120 may be curled. In a curled state, the first coil units 111 and the second coil unit 121 may be arranged on a curved surface, at this time, the stacked direction refers to a direction perpendicular to a tangent surface of the second coil unit 121 or the second coil assembly 120.

A projection of a center of each of the at least one second coil unit 121 on the first coil assembly 110 along the stacked direction may have a distance from a center of each of the at least two first coil units 111, which may be understood that the projection of the center of each second coil unit 121 in the second coil assembly 120 on the first coil assembly 110 along the stacked direction may misalign with the center of each first coil unit in the first coil assembly 110. The center of each of the at least two first coil units 111 refers to a geometric center of the first coil unit 111. The center of each second coil unit 121 refers to a geometric center of the second coil unit 121. When the first coil unit 111 and/or the second coil unit 121 is a regular shape (e.g., a circle, a square, a rectangle, etc.), the center of each of the at least two first coil units 111 and/or the center of each second coil unit 121 may be determined by using a geometric manner (e.g., a symmetry manner, a feature point manner, a geometric parameter manner, etc.). When the first coil unit 111 and/or the second coil unit 121 is an irregular shape, the irregular shape may be divided into a plurality of regular shapes. The geometric center of each of the plurality of regular shapes may be determined, an average value of the geometric centers of all regular shapes may be determined, and then the center of the first coil unit 111 and/or the center of the second coil unit 121 may be determined based on the average value. For example, the average value of the geometric centers of all regular shapes may be designated as the center of the first coil unit 111 and/or the center of the second coil unit 121. Since a signal strength at the center of each of a coil unit is the strongest, by such a setup, signals of the first coil assembly 110 and the second coil assembly 120 may be made to be complementary (the second coil unit 121 may be complementary for non-center locations of each of the first coil units with a weaker signal strength). Thus, uniformity of a synthesized signal-to-noise ratio or a signal distribution in the region of interest may be improved while improving the parallel imaging capability of the AP direction and the other encoding directions (e.g., an up-to-down direction, a right-to-left direction), thereby avoiding uneven brightness of the image and improve the uniformity of the image. Additionally, B1 field interference between a plurality of channels of the first coil assembly 110 and the second coil assembly 120 may be reduced to minimize the B1 field interference, and the signal-to-noise ratio and the parallel imaging capability in the AP direction and the other encoding directions (e.g., an up-to-down direction, a right-to-left direction) may further be improved, which further may improve image quality. For example, as shown in FIG. 1 and FIG. 2, the projection of the center O of the second coil unit 121 on the first coil assembly 110 along the stacked direction has a distance D1 from a center A of the first coil unit 111-1, and the projection of the center O of the second coil unit 121 on the first coil assembly 110 along the stacked direction has a distance D2 from a center B of the first coil unit 111-2. As another example, as shown in FIG. 3-FIG. 4, FIG. 5C, FIG. 6C, FIG. 7C, FIG. 8C, FIG. 9, and FIG. 10, the projection of the center of each second coil unit 121 in the second coil assembly 120 on the first coil assembly 110 along the stacked direction has a distance from the center of each first coil unit in the first coil assembly 110.

In some embodiments, as shown in FIG. 1-FIG. 4, FIG. 5C, FIG. 6C, FIG. 7C, FIG. 8C, FIG. 9, and FIG. 10, the first coil assembly 110 may be arrayed in a matrix in the XY plane or a plane parallel to the XY plane, i.e., the first coil units 111 may be arranged in a matrix along the first direction (also referred to as the X direction) and the second direction (also referred to as the Y direction). In some embodiments, adjacent first coil units in the first direction and/or the second direction may be arranged at intervals. For example, as shown in FIG. 1, the adjacent first coil unit 111-1 and the first coil unit 111-2 are arranged at an interval in the first direction (referred to as the X direction). When the first coil units 111 are arranged at intervals, the first coil assembly 110 may include a component such as a capacitor, an inductor, etc., for decoupling. As used herein, adjacent coil units refer to two coil units between which no other coil unit is located.

In some embodiments, the at least two first coil units 111 may be arranged in the first direction. The projection of the center of each of the at least one second coil unit 121 on the first coil assembly 110 along the stacked direction may be located between centers of two adjacent first coil units in the first direction. In some embodiments, a region between the centers of the first coil units adjacent in the first direction refers to a region between centerlines of the first coil units 111 adjacent in the first direction. A centerline of a first coil unit may cross the center of the first coil unit, be located in the plane in which the first coil assembly 110 is located and be perpendicular to the first direction. For example, as shown in FIG. 1 and FIG. 3, the first coil unit 111-1 is adjacent to the first coil unit 111-2 and arranged along the first direction (also referred to as the X direction), and the projection of the center O of the second coil unit 121 on the first coil assembly 110 along the stacked direction is located in a region between a centerline m of the first coil unit 111-1 and a centerline n of the first coil unit 111-2. In some embodiments, the projection of the center of each of the at least one second coil unit 121 on the first coil assembly 110 along the stacked direction may be located on a line connecting the centers of the adjacent first coil units 111 in the first direction. For example, as shown in FIG. 1 and FIG. 3, the first coil unit 111-1 and the first coil unit 111-2 are adjacent to each other and arranged along the first direction (also referred to as the X direction), and the projection of the center O of the second coil unit 121 on the first coil assembly 110 along the stacked direction is located on a line AB connecting the center A of the first coil unit 111-1 and the center B of the first coil unit 111-2.

In some embodiments, at least two first coil units 111 may be arranged along the second direction. The second direction may be perpendicular to the first direction. The projection of the center of each of the at least one second coil unit 121 on the first coil assembly 110 along the stacked direction may be located between centers of two adjacent first coil units 111 in the second direction. In some embodiments, a region between the centers of the two adjacent first coil units 111 in the second direction refers to a region between centerlines of the two adjacent first coil units 111 in the second direction. The centerlines of the two first coil units 111 may be located in a plane in which the first coil assembly 110 is located and perpendicular to the second direction. For example, as shown in FIG. 2 and FIG. 4, the first coil unit 111-1 and the first coil unit 111-2 are adjacent to each other and arranged along the second direction (also referred to as the Y direction), and the projection of the center O of the second coil unit 121 on the first coil assembly 110 along the stacked direction is located in a region between a centerline h of the first coil unit 1111-1 and a centerline I of the first coil unit 111-2. In some embodiments, the projection of the center of each of the at least one second coil unit 121 on the first coil assembly 110 along the stacked direction may be located on a line connecting the centers of the adjacent first coil units 111 in the second direction. For example, as shown in FIG. 2 and FIG. 4, the first coil unit 111-1 and the first coil unit 111-2 are adjacent to each other and are arranged along the second direction (also referred to as the Y direction), and the projection of the center O of the second coil unit 121 on the first coil assembly 110 along the stacked direction is located on a line AB connecting a center A of the first coil unit 111-1 and a center B of the first coil unit 111-2.

In some embodiments, the projection of the center of each of the at least one second coil unit 121 on the first coil assembly 110 along the stacked direction may be located at a midpoint of the line connecting the centers of the adjacent first coil units 111 in the first direction to further improve the uniformity of the synthesized signal-to-noise ratio or the signal distribution in the region of interest, thereby improving the uniformity of the image. For example, as shown in FIG. 1 and FIG. 3, the first coil unit 111-1 and the first coil unit 111-2 are adjacent to each other and arranged along the first direction (also referred to as the X direction), and the projection of the center O of the second coil unit 121 on the first coil assembly 110 along the stacked direction is located on the line AB connecting the center A of the first coil unit 111-1 and the center B of the first coil unit 111-2, and the center O is located at a midpoint of the line AB, i.e., D1=D2.

In some embodiments, the projection of the center of each of the at least one second coil unit 121 on the first coil assembly 110 along the stacked direction may be located at a midpoint of the line connecting the centers of the adjacent first coil units 111 in the second direction to further improve the uniformity of the synthesized signal-to-noise ratio or the signal distribution in the region of interest and improve the uniformity of the image. For example, as shown in FIG. 2 and FIG. 4, the first coil unit 111-1 and the first coil unit 111-2 are adjacent to each other and arranged along the second direction (also referred to as the Y direction), and the projection of the center O of the second coil unit 121 on the first coil assembly 110 along the stacked direction is located on the line AB between the center A of the first coil unit 111-1 and the center B of the first coil unit 111-2, and the center O is located at the midpoint of the line AB, i.e., D1=D2.

In some embodiments, two adjacent first coil units 111 of the first coil assembly 110 may be partially overlapped, and the projection of the center of each of the at least one second coil unit 121 on the first coil assembly 110 along the stacked direction may be located in an overlapped region between the two adjacent first coil units 111. In some embodiments, the projection of the center of each of the at least one second coil unit 121 on the first coil assembly 110 along the stacked direction may be located at a center of the overlapped region. The center of the overlapped region refers to a geometric center of the overlapped region. When the overlapped region is a regular shape (e.g., a circle, a square, a rectangle, etc.), the center of the overlapped region may be determined by using a geometric manner (e.g., a symmetry manner, a feature point manner, a geometric parameter manner, etc.). When the overlapped region is an irregular shape, the irregular shape may be divided into a plurality of regular shapes. A geometric center of each of the plurality of regular shapes may be determined, an average value of the geometric centers of all regular shapes may be determined, and then the center of the overlapped region may be determined based on the average value. For example, the average value of the geometric centers of all regular shapes may be designated as the center of the overlapped region.

In some embodiments, the first coil units 111 adjacent in the first direction may be arranged at an interval, and/or the first coil units 111 adjacent in the second direction may also be arranged at an interval. When the first coil units 111 are arranged at intervals, the first coil assembly 110 may include one or more components such as a capacitor, an inductor, etc., for decoupling. In some embodiments, two adjacent first coil units 111 in the first direction may be partially overlapped, and/or the two adjacent first coil units 111 in the second direction may be partially overlapped to achieve decoupling. For example, as shown in FIG. 3, the first coil unit 111-1 and the first coil unit 111-2 are adjacent to each other and arranged along the first direction (also referred to as the X direction), the first coil unit 111-1 and the first coil unit 111-2 are partially overlapped in the first direction (also referred to as the X direction). As another example, as shown in FIG. 4, the first coil unit 111-1 and the first coil unit 111-2 are adjacent to each other and arranged in the second direction (also referred to as a Y direction), the first coil unit 111-1 and the first coil unit 111-2 are partially overlapped in the second direction (also referred to as the Y direction). As another example, as shown in FIG. 5C, FIG. 6C, FIG. 7C, and FIG. 8C, four first coil units adjacent in the first direction (also referred to as the X direction) and the second direction (which is also referred to as the Y direction) are partially overlapped to form a common overlapped region denoted as Z in FIG. 5C (also referred to as a third overlapped region hereinafter).

In some embodiments, the projection of the center of each of the at least one second coil unit 121 on the first coil assembly 110 along the stacked direction may be located in a first overlapped region of the first coil units 111 adjacent in the first direction. In some embodiments, the projection of the center of each of the at least one second coil unit 121 on the first coil assembly 110 along the stacked direction may be located at a center of the first overlapped region of the first coil units 111 adjacent in the first direction. For example, as shown in FIG. 3, the first coil unit 111-1 and first coil unit 111-2 adjacent in the first direction (also referred to as the X direction) are partially overlapped to form a first overlapped region M. The projection of the center O of the second coil unit 121 on the first coil assembly 110 along the stacked direction is located in the first overlapped region M, and the center O is located at the same position as the center of the first overlapped region M.

In some embodiments, the projection of the center of each of the at least one second coil unit 121 on the first coil assembly 110 along the stacked direction may be located in a second overlapped region of the first coil units 111 adjacent in the second direction. In some embodiments, the projection of the center of each of the at least one second coil unit 121 on the first coil assembly 110 along the stacked direction may be located at a center of the second overlapped region of the first coil units 111 adjacent in the second direction. For example, as shown in FIG. 4, the first coil unit 1 111-1 and first coil unit 111-2 adjacent in the second direction (also referred to as the Y direction) are partially overlapped to form the second overlapped region N. The projection of the center O of second coil unit 121 on the first coil assembly 110 along the stacked direction is located in the second overlapped region N, and the center O is located at the same position as the center of the second overlapped region N.

In some embodiments, at least four first coil units 111 may be arrayed in an array in the first direction and the second direction, and each two of four first coil units 111 may be adjacent to and overlapped with each other in the first direction and the second direction (e.g., four adjacent first coil units arranged in a 2*2 matrix), thus the four first coil units 111 may have a third overlapped region, and the projection of the center of each of the at least one second coil unit 121 may be located on the first coil assembly 110 along the stacked direction in the third overlapped region. In some embodiments, the projection of the center of each of the at least one second coil unit 121 on the first coil assembly 110 along the stacked direction may be located at the third overlapped region. It may be understood that when the projection of the center of the at least one second coil unit 121 on the first coil assembly 110 along the stacked direction is located at the third overlapped region, the projection of the center of the at least one second coil unit 121 on the first coil assembly 110 along the stacked direction may be located at the first overlapped region of the first coil units 111 adjacent in the first direction, and the projection of the center of the at least one second coil unit 121 on the first coil assembly 110 along the stacked direction may also be located at the second overlapped region of the first coil units 111 adjacent in the second direction. The four adjacent first coil units arranged in an array along the first direction (also referred to as the X direction) and the second direction (also referred to as the Y direction) may have the third overlapped region P. The projection of the center O of each of the at least one second coil unit 121 on the first coil assembly 110 along the stacked direction may be located in the third overlapped region P, and the center O may be at the same position as the center of the third overlapped region P to form a reinforcement region (such as the region shown by dash-dotted lines in FIG. 5C, FIG. 6C, FIG. 7C, FIG. 8C, FIG. 9, and FIG. 10). MR signals received by the reinforced region may have a uniform synthesized signal-to-noise ratio or signal distribution, and accordingly, the MRI image generated based on the MR signals received by the reinforced region may be more uniform and the image quality may be higher. For example, FIG. 5A illustrates a first coil assembly 110 including four first coil units 111. The four first coil units 111 may be arranged in a 2*2 matrix and have a third overlapped region P. FIG. 5B illustrates a second coil assembly 120 including a second coil unit 121, a center of the second coil unit 121 may be point O. The first coil assembly 110 as shown in FIG. 5A and the second coil assembly 120 as shown in FIG. 5B may be arranged in the stacked configuration to form the reinforced region as shown in FIG. 5C. As shown in FIG. 5C, the projection of the center O of the second coil unit 121 on the first coil assembly 110 along the stacked direction is located at the center of the third overlapped region P. As another example, FIG. 6A illustrates a first coil assembly 110 including nine first coil units 111. The nine first coil units 111 are arranged in a 3*3 matrix, and every four first coil units 111 adjacent to each other in the first direction (also referred to as the X direction) and the second direction (also referred to as the Y direction) may have the overlapped region P, thus the first coil assembly 110 may involve four third overlapped regions. FIG. 6B illustrates a second coil assembly 120 including nine second coil units 121 arranged in a 3*3 matrix, and the center of each of the nine second coil units 121 is the point O. The first coil assembly 110 as shown in FIG. 6A and the second coil assembly 120 as shown in FIG. 6B may be arranged in the stacked configuration to form the reinforced regions as shown in FIG. 6C. As shown in FIG. 6C, projections of centers O of the four second coil units 121 of the second coil assembly 120 on the first coil assembly 110 along the stacked direction are located at centers of four third overlapped regions Z, respectively. As another example, FIG. 7A illustrates the first coil assembly 110 including fifteen first coil units 111. The fifteen first coil units 111 are arranged in a 3*5 matrix, and every four first coil units 111 adjacent to each other in the first direction (also referred to as the X direction) and the second direction (also referred to as the Y direction) may have a third overlapped region P, thus the first coil assembly 110 including fifteen first coil units 111 may involve eight third overlapped regions. FIG. 7B illustrates a second coil assembly 120 including eight second coil units 121 arranged in a 2*4 matrix, a center of each of the eight second coil units 121 may be denoted as point O. The first coil assembly 110 as shown in FIG. 7A and the second coil assembly 120 as shown in FIG. 7B may be arranged in the stacked configuration to form the reinforced regions as shown by dash-dotted lines in FIG. 7C. As shown in FIG. 7C, projections of centers O of the eight second coil units 121 in the second coil assembly 120 on the first coil assembly 110 along the stacked direction are located at centers of the eight third overlapped regions Z, respectively. As another example, FIG. 8A illustrates the first coil assembly 110 including six first coil units 111. The six first coil units 111 are arranged in a 2*3 matrix, and every four first coil units 111 adjacent to each other in the first direction (also referred to as the X direction) and the second direction (also referred to as the Y direction) has a third overlapped region P, thus the first coil assembly 110 may involve two third overlapped regions. FIG. 8B illustrates a second coil assembly 120 including six second coil units 121 arranged in a 3*2 matrix, a center of each of the six second coil units 121 is the point O. The first coil assembly 110 as shown in FIG. 8A and the second coil assembly 120 as shown in FIG. 8B may be arranged in the stacked configuration to form the reinforced regions as shown in FIG. 8C. As shown in FIG. 8C, projections of the centers O of the two second coil units 121 in the second coil assembly 120 on the first coil assembly 110 along the stacked direction are located at centers of the two third overlapped regions P, respectively. As another example, FIG. 9 illustrates a first coil assembly 110 including twelve first coil units 111. The twelve first coil units 111 are arranged in a 2*6 matrix, and every four first coil units 111 adjacent to each other in the first direction (also referred to as the X direction) and the second direction (also referred to as the Y direction) have a third overlapped region P, thus the first coil assembly 110 including twelve first coil units 111 may involve five third overlapped regions. FIG. 9 also illustrates a second coil assembly 120 including twelve second coil units 121 arranged in a 6*2 matrix, a center of each of the twelve second coil units 121 may be denoted as the point O. The first coil assembly 110 and the second coil assembly 120 in FIG. 9 may be arranged in the stacked configuration to form the reinforced regions as shown by dash-dotted lines in FIG. 9. Projections of centers O of the two second coil units 121 of the second coil assembly 120 in FIG. 9 along the stacked direction on the first coil assembly 110 may be located at centers of the two third overlapped regions Z, respectively. As another example, FIG. 10 illustrates a first coil assembly 110 including twelve first coil units 111. The twelve first coil units 111 are arranged in a 2*6 matrix, and every four first coil units 111 adjacent to each other in the first direction (also referred to as the X direction) and the second direction (also referred to as the Y direction) have a third overlapped region P, thus the first coil assembly 110 may involve five third overlapped regions. FIG. 9 also illustrates a second coil assembly 120 including twelve second coil units 121, which are also arranged in a 2*6 matrix, a center of each of the second coil units 121 may be denoted as the point O. The first coil assembly 110 and the second coil assembly 120 in FIG. 10 may be arranged in the stacked configuration to form a reinforced region as shown by dash-dotted lines in FIG. 10. In FIG. 10, projections of centers O of the five second coil units 121 of the second coil assembly 120 along the stacked direction on the first coil assembly 110 are located at centers of the five third overlapped regions Z, respectively. It should be understood that the first coil assembly 110 and the second coil assembly 120 may also be of other counts and/or arrangements according to the clinical needs (e.g., information related to the region of interest). In some embodiments, the information related to the region of interest may include but is not limited to a location, a size, etc. of the region of interest.

In some embodiments, when the second coil assembly 120 includes at least two second coil units 121 arranged in an array, the at least two second coil units 121 may be arranged along a third direction and/or a fourth direction. A situation in which the at least two second coil units 121 are arranged along the third direction may be similar to a situation in which the at least two first coil units 111 are arranged along the first direction. The third direction and the first direction may be parallel or have an included angle greater than 0° and less than 180°. An arrangement of the at least two second coil units 121 along the fourth direction may be similar to an arrangement of the at least two first coil units 111 along the second direction. The fourth direction and the second direction may be parallel or have an angle greater than 0° and less than 180º. In some embodiments, a plane in which the third direction and the fourth direction are located may be parallel or approximately parallel to the plane in which the first direction and the second direction are located.

In some embodiments, the second coil units 121 adjacent in the third direction and/or fourth direction may be arranged at an interval. When the second coil unit 121 is arranged at an interval, the second coil assembly 120 may include one or more components such as a capacitor, an inductor, etc. for decoupling. In some embodiments, at least two second coil units 121 of the second coil assembly 120 may be partially overlapped to form an overlapped region to achieve decoupling. It should be understood that the second coil assembly 120 may have the same or similar arrangement as the first coil assembly 110 when used alone.

In some embodiments, the surface coil 100 may have one or more through holes 190 along a thickness direction of the surface coil 100. For example, the one or more through holes 190 may include a first hollow hole 220 provided on a first cladding layer 210. As another example, the one or more through holes 190 may include a plurality of second hollow holes 320 provided on a second cladding layer 310 and a plurality of third hollow holes 420 provided on a third cladding layer 410. As another example, the one or more through holes 190 may form the hollow structure 160.

In some embodiments, the surface coil 100 may be configured to have a first surface coil 200, the first surface coil 200 may include the first coil assembly 110 and the second coil assembly 120.

The first surface coil 200 may include the first coil assembly 110 and the second coil assembly 120 so that at least a portion of the at least two first coil units 111 of the first coil assembly 110 may be arranged in stacked configuration with each of at least one second coil unit 121 of the second coil assembly 120 to achieve joint use. Sizes of the first coil assembly 110 and the second coil assembly 120 may be the same or different. A count of coil units (e.g., the first coil units 111 and the second coil unit 121) of the first coil assembly 110 and a count of coil units of the second coil assembly 120 may be the same or different. In some embodiments, the stacked configuration refers to a plane in which the first coil assembly 110 is located is parallel or approximately parallel to a plane in which the second coil assembly 120 is located, and the at least one second coil unit 121 in the second coil assembly 120 is at least partially overlapped with at least one of the at least two first coil units 111 in the first coil assembly 110.

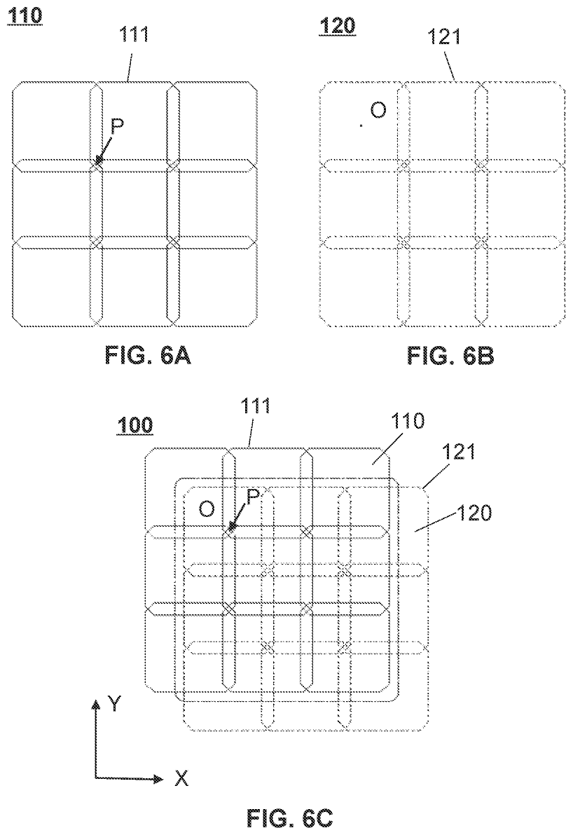

In some embodiments, the first surface coil 200 may further include a first cladding layer 210, both the first coil assembly 110 and the second coil assembly 120 may be encased within the first cladding layer 210. In some embodiments, the one or more through holes 190 may include one or more first hollow holes 220 provided on the first cladding layer 210. FIG. 11 is a schematic diagram illustrating an exemplary first surface coil according to some other embodiments of the present disclosure. In some embodiments, as shown in FIG. 11, the first surface coil 200 may include a first cladding layer 210 for cladding the first coil assembly 110 and the second coil assembly 120. The first surface coil 200 may include the first coil assembly 110 arranged in a 2*6 matrix and the second coil assembly 120 arranged in a 1*5 matrix. The first coil assembly 110 and the second coil assembly 120 may both be encased within the first cladding layer 210. In some embodiments, as shown in FIG. 11, the first cladding layer 210 may be provided with multiple first hollow holes 220 for improving breathability and heat dissipation to further improve the user's experience and increase the scanning success rate.

In some embodiments, the first cladding layer 210 may be provided with the first hollow holes at positions corresponding to the first overlapped region, the second overlapped region, and/or the third overlapped region for further improving the breathability and heat dissipation. For example, as shown in FIG. 9, the first hollow hole 220 is provided on the first cladding layer 210 corresponding to the first overlapped region M and the second overlapped region N.

In some embodiments, as shown in FIG. 12 and FIG. 13, the surface coil 100 may be configured to have a second surface coil 300 and a third surface coil 400, the second surface coil 300 may include the first coil assembly 110, and the third surface coil 400 may include the second coil assembly 120. The second surface coil 300 may be detachably connected with the third surface coil 400.

The second surface coil 300 and the third surface coil 400 may be used independently. The second surface coil 300 and the third surface coil 400 may be detachably connected. The at least two first coil units 111 of the first coil assembly 110 and at least one second coil unit 121 of the second coil assembly 120 may be arranged in a stacked configuration to realize joint use. The second surface coil 300 may be detachably connected with the third surface coil 400 using an adhesive connection, a snap-fit connection, etc. More descriptions regarding the connection between the second surface coil 300 and the third surface coil 400 may be found elsewhere in the present disclosure. The sizes of the first coil assembly 110 and the second coil assembly 120 may be the same or different. The count of coil units in the first coil assembly 110 and the count of coil units in the second coil assembly 120 may be the same or different. More descriptions for the stacked configuration may be found elsewhere in the present disclosure.

It should be noted that the arrangement of the at least one second coil unit 121 may be set according to a brightness of an image generated based on MR signals received by the first coil assembly 110. For example, the second coil unit 121 may be arranged at a position corresponding to a position of the first coil units 111 for receiving MRI signals that are used for reconstructing an image with a lower brightness. As another example, the second coil unit 121 is provided at a position corresponding to a region in which the brightness of the image is required to be further enhanced.

The second surface coil 300 and the third surface coil 400 in the embodiments of the present disclosure may be detachably connected, which enables the second surface coil 300 and the third surface coil 400 to be used independently as well as at the same time (e.g., in the stacked configuration). Not only the cost may be reduced, but also the first coil assembly 110 and the second coil assembly 120 may be used in different combinations according to clinical needs to apply to a plurality of scanning scenarios with high image quality (e.g., with high signal-to-noise ratio and parallel imaging capability). In the embodiments of the present disclosure, the at least a portion of the at least two first coil units 111 of the first coil assembly 110 and the at least one second coil unit 121 of the second coil assembly 120 may be arranged in the stacked configuration, which not only improves the signal-to-noise ratio of the overlapped region and the parallel imaging capability of the AP direction and other coding directions (e.g., an up-to-down direction, a left-to-right direction) to further improve the image quality, but also increases a scanning coverage area when the projection of the second coil assembly 120 on the first coil assembly 110 along the stacked direction is partially overlapped with the first coil assembly 110 (e.g., as shown in FIG. 6).

In some embodiments, the second surface coil 300 may further include a second cladding layer 310, and the second cladding layer 310 may clad the first coil assembly 110. The third surface coil 400 may further include a third cladding layer 410, and the third cladding layer 410 may clad the second coil assembly 120. In some embodiments, the second cladding layer 310 may be detachably connected with the third cladding layer 410. FIG. 12 is a schematic diagram illustrating an exemplary second surface coil according to some embodiments of the present disclosure. In some embodiments, as shown in FIG. 12, the second surface coil 300 may include a second cladding layer 310 for cladding at least two first coil assemblies. FIG. 13 is a schematic diagram illustrating an exemplary third surface coil according to some r embodiments of the present disclosure. In some embodiments, as shown in FIG. 9, the third surface coil 400 may also include a third cladding layer 410 for cladding at least one second coil assembly 120. The second cladding layer 310 and the third cladding layer 410 may be used for cladding the first coil assembly 110 and the second coil assembly 120, respectively, in order to allow the first coil assembly 110 and the second coil assembly 120 to operate independently.

In some embodiments, the second cladding layer 310 and the third cladding layer 410 may be detachably connected to enable the second surface coil 300 to be detachably connected with the third surface coil 400. In some embodiments, the second cladding layer 310 and the third cladding layer 410 may be detachably connected via Velcro. The arrangement of Velcro may make a relative position of the second surface coil 300 and the third surface coil 400 easy to be adjusted, and a connection area between the second surface coil 300 and the third surface coil 400 may be larger, and the connection between the second surface coil 300 and the third surface coil 400 may be more stable. In some embodiments, the second cladding layer 310 and the third cladding layer 410 may be detachably connected by other means, such as a snap structure including a button, a buttonhole, etc.

In some embodiments, at least one of the second cladding layer 310 and/or the third cladding layer 410 may be provided with at least one positioning mark for indicating the relative position of the connection of the second surface coil 300 with the third surface coil 400 so that the relative position of the first coil assembly 110 and the second coil assembly 120 may be determined quickly during a cladding process. Taking the second cladding layer 310 as an example, a positioning mark on the second cladding layer 310 may be a dot indicating a center of a first coil unit. Alternatively, the positioning mark on the second cladding layer 310 may be a dot indicating a center of an overlapped region of the first coil assembly 110. Furthermore, the positioning mark on the second cladding layer 310 may be a contour line indicating a placement position of the second coil assembly 120.

In some embodiments, as shown in FIG. 12, the one or more through holes 190 may include one or more second hollow holes 320 provided on the second cladding layer 310. The second hollow holes 320 may penetrate the first coil assembly 110 along a thickness direction of the first coil assembly 110 (i.e., an axial direction of the first coil unit). In some embodiments, the second hollow holes 320 may be arranged in a region of the second cladding layer 310 where the first coil unit 111 is located. In some embodiments, the second hollow hole 320 may be arranged in a region of the second cladding layer 310 where an overlapped region is located, and the overlapped region is formed by at least two first coil units 111 partially overlapping. In some embodiments, the second cladding layer 310 may be provided with a plurality of second hollow holes to enhance heat dissipation of the first coil assembly 110.

In some embodiments, as shown in FIG. 13, the one or more through holes 190 may include one or more third hollow holes 420 provided on the third cladding layer 410. The third hollow holes 420 may penetrate the second coil assembly 120 along a thickness direction of the second coil assembly 120 (i.e., an axial direction of the second coil unit 121). In some embodiments, the third hollow holes 420 may be arranged in a region of the third cladding layer 410 where the second coil unit 121 is located. In some embodiments, the third hollow hole 420 may be arranged in a region of the third cladding layer 410 where an overlapped region is located, and the overlapped region is formed by the at least two of the second coil units 121 partially overlapping. In some embodiments, the third cladding layer 410 may be provided with a plurality of third hollow holes to enhance heat dissipation of the second coil assembly 120.

The hollow holes (including the second hollow holes 320 and the third hollow holes 420) may be used to improve air permeability and heat dissipation of the coil assemblies (including the first coil assembly 110 and the second coil assembly 120), thereby improving the user's scanning experience and improving the scanning success rate.

FIG. 14, FIG. 15, and FIG. 16 are schematic diagrams illustrating exemplary surface coils according to some embodiments of the present disclosure.

The second surface coil 300 shown in FIG. 12 and the third surface coil 400 shown in FIG. 13 may be used individually or in a stacked configuration to form the surface coil 100 as shown in FIG. 14. FIG. 14 illustrates a first coil assembly 110 and a second coil assembly 120 with different sizes and counts of coil units (the first coil assembly 110 includes twelve first coil units 111 and the second coil assembly 120 includes eight second coil units 121). The first coil assembly 110 and the second coil assembly 120 in the surface coil 100 shown in FIG. 15 are arranged in the same manner as the first coil assembly 110 and the second coil assembly 120 in the surface coil 100 shown in FIG. 9. The first coil assembly 110 and the second coil assembly 120 in the surface coil 100 shown in FIG. 16 are arranged in the same manner as the first coil assembly 110 and the second coil assembly 120 in the surface coil 100 shown in FIG. 10. Both FIG. 15 and FIG. 16 (or FIG. 9 and FIG. 10) illustrate the first coil assembly 110 and the second coil assembly 120 having the same sizes and the same counts of the coil units (the first coil assembly 110 includes twelve first coil units 111 and the second coil assembly 120 includes twelve second coil units 121), but FIG. 15 and FIG. 16 (or FIG. 9 and FIG. 10) illustrate different relative positional relationships of the first coil assembly 110 and the second coil assembly 120, respectively, during joint use. FIG. 15 (or FIG. 9) illustrates the surface coil 100 that six first coil units 111 per row arranged along a first direction (also referred to as an X direction), and six second coil units 121 per column arranged along a second direction (also referred to as a Y direction), and a projection of each of centers of two second coil units 121 on the first coil assembly 110 along the stacked direction at a center of an overlapped region of four first coil units 111. The surface coil 100 shown in FIG. 15 (or FIG. 9) may increase in a scanning coverage area dramatically. FIG. 16 (or FIG. 10) illustrates the surface coil 100 that six first coil units 111 per row and six second coil units 121 per row are all arrayed in the first direction (also referred to as the X direction), and a projection of a center of each of five second coil units 121 on the first coil assembly 110 along the stacked direction is located at the center of the overlapped region of four first coil units 111.

In some embodiments, as shown in FIG. 14, FIG. 15, and FIG. 16, the one or more through holes 190 may include a plurality of second hollow holes 320 provided on the second cladding layer 310 and a plurality of third hollow holes 420 provided on the third cladding layer 410. When the first coil assembly 110 and the second coil assembly 120 are overlapped, positions of the second hollow holes 320 may correspond to a position of a portion of the third cladding layer 410 (e.g., a portion of conductive wires of the second coil unit 121), and positions of the third hollow holes 420 may correspond to a position of a portion of the second cladding layer 310 (e.g., a portion of the conductive wires of the first coil unit 111), to achieve matching and coordinated operation between the first coil assembly 110 and the second coil assembly 120. In embodiments of the present disclosure, corresponding may be understood as corresponding in position. Also, the second hollow hole 320 and the third hollow hole 420 may be arranged for convenience for an operator to observe during a stacking process, to determine the relative positions of the first coil assembly 110 and the second coil assembly 120 quickly.

During an MRI scanning process, since the human organ is a consumptive medium, the electromagnetic field in the body may generate an electric current, which absorbs and dissipates the electromagnetic energy, causing the body to heat up. Currently, most surface coils have a flat design, and the technician needs to wrap the surface coil around the human's area for scanning. Self-heating of the organs due to the electromagnetic field combined with the cladding of the closed surface coil may easily cause the human to feel stuffy and uncomfortable and not be able to resist moving around, resulting in a failed scan, especially pronounced in high-field systems that are prone to heat and sensitive to motion. Therefore, it is necessary to provide a radio frequency device that improves the heat dissipation performance of the radio frequency device.

In some embodiments, an outer skin of the surface coil (e.g., the first cladding layer 210, the second cladding layer 310, and the third cladding layer 410, as described above) may be cladded in a semi-flexible material such as EVA. The semi-flexible material may be molded in a form of a compression mold, which allows for a direct formation of a hollow structure and is mostly used in coils with low field strength and large coil unit. Because of the features of the semi-flexible material, the surface coil may not be very adherent to the subject, so overall the problems caused by heating are not obvious.

In some embodiments, the outer skin of the surface coil (e.g., the first cladding layer 210, the second cladding layer 310, and the third cladding layer 410, as described above) may be made of a stacked flexible fabric. However, a structural strength of the stacked flexible fabric is not strong enough to set up a further structure for heat dissipation to realize heat dissipation of the surface coil. Additionally, in a high field strength system, a count of coil units provided is large, a size of the coil unit is small, and there are a plurality of hard radio frequency components with fixed size (e.g., capacitive components, inductive components, etc.) inside the surface coil, thus, usually there is not enough space to arrange a hollow structure including multiple hollow holes. Embodiments of the present disclosure provide a radio frequency device. The surface coil of the radio frequency device may include an arrangement layer for arranging a coil assembly, a fourth cladding layer for covering the coil assembly, and a sealing structure. The fourth cladding layer may form an outer skin for covering the coil assembly. The hollow structure may be formed on the arrangement layer and the fourth cladding layer, and the hollow structure may facilitate heat dissipation of the radio frequency device when using. The sealing structure may, on the one hand, strengthen the structural strength of the surface coil, and on the other hand, may seal and connect the arrangement layer and the fourth cladding layer at the hollow structure to ensure that the coil assembly is isolated from the external environment, so as to enable the coil assembly to work safely and stably. Additionally, by setting up a transmission segment for tuning and a transmission line for impedance matching. It is no longer necessary to arrange the capacitive component or the inductive component on the radio frequency device, which may make it possible to set up more hollow structures on the surface coil with more space, allowing for better heat dissipation of the radio frequency device.

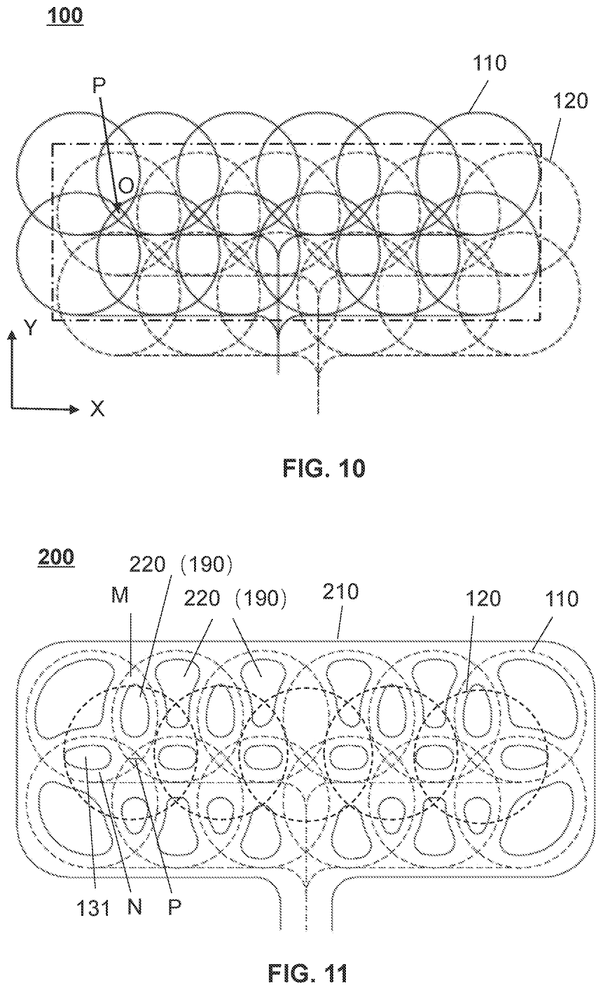

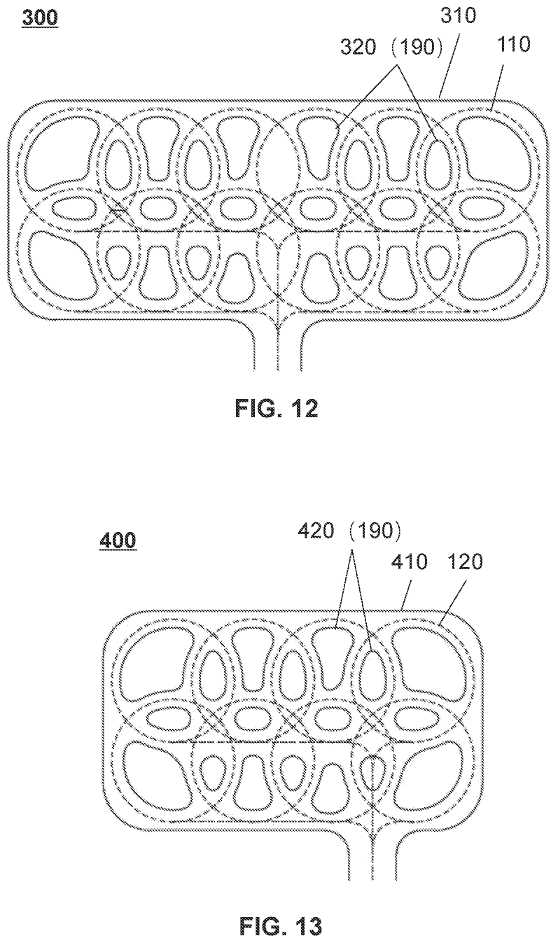

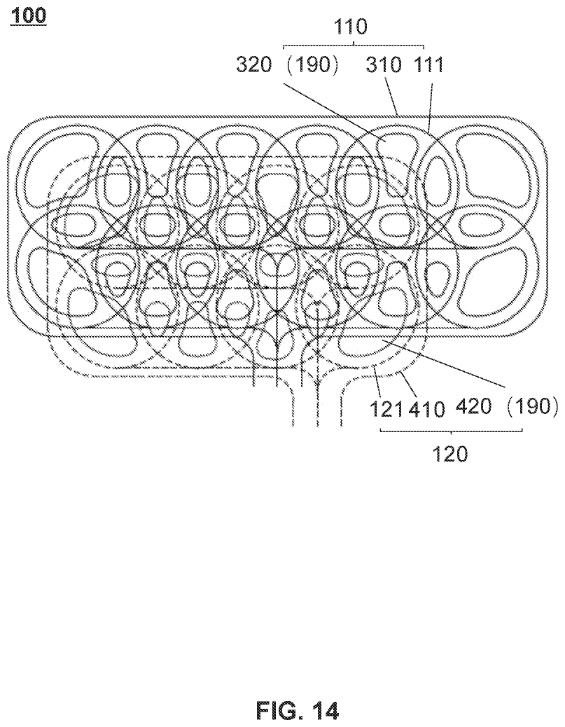

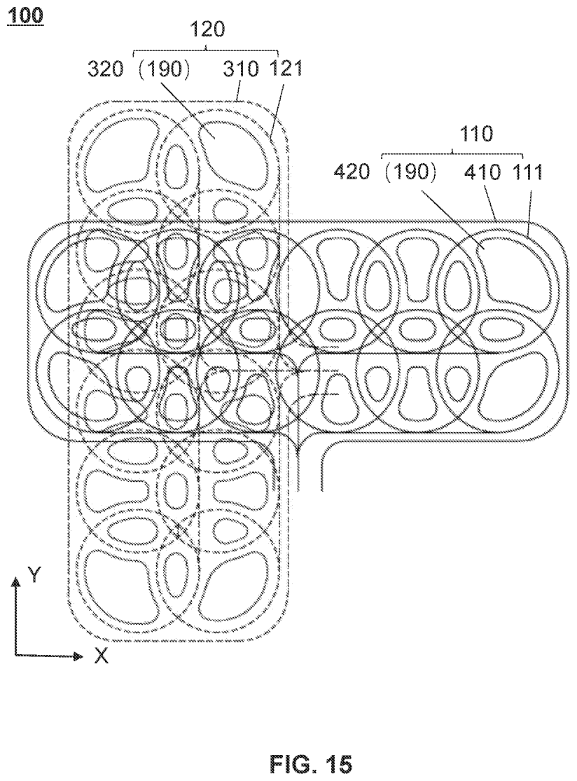

FIG. 17 is a schematic diagram illustrating an exemplary radio frequency device according to some embodiments of the present disclosure. FIG. 18 is a schematic diagram illustrating an exemplary arrangement layer, a hollow structure, and a coil assembly of a radio frequency device according to some embodiments of the present disclosure. FIG. 19 is a schematic diagram illustrating an exemplary part A of a radio frequency device in FIG. 17. FIG. 20 is a diagram illustrating a B-B cross-sectional view of part A of a radio frequency device in FIG. 19.

As shown in FIG. 17-FIG. 20, the present disclosure provides a radio frequency device 1000. The radio frequency device 1000 may include a surface coil 100 (such as a first surface coil 200, a second surface coil 300, and a third surface coil 400 as described above). The surface coil 100 may include a coil assembly 130, an arrangement layer 140, a fourth cladding layer 150, and a sealing structure 170. Both the arrangement layer 140 and the fourth cladding layer 150 may be flexible to allow the surface coil 100 to fit more closely to the part of the human body to be scanned. The coil assembly 130 may be at least one of the first coil assembly 110 and the second coil assembly 120. The coil assembly 130 may be configured to emit and/or receive a magnetic resonance signal, and the coil assembly 130 may be arranged on the arrangement layer 140, and the arrangement layer 140 may carry and fix the coil assembly 130. The fourth cladding layer 150 may be provided on the arrangement layer 140 and cover at least the coil assembly 130. The fourth cladding layer 150 may be configured to protect the coil assembly 130, and the fourth cladding layer 150 may contact the skin of a subject to be scanned when the radio frequency device 1000 is operating. The one or more through holes 190 may form the hollow structure 160. The hollow structure 160 may be formed on the arrangement layer 140 and the fourth cladding layer 150. The hollow structure 160 may facilitate heat dissipation of the radio frequency device 1000 when used, thereby improving a heat dissipation performance of the radio frequency device 1000. It should be noted that the hollow structure 160 may be of the same structure as the first hollow holes 220, the second hollow holes 320, and the third hollow holes 420 as described elsewhere in the present disclosure. And the aforementioned first cladding layer 210, the second cladding layer 310, and the third cladding layer 410 may be provided with structures similar to the hollow structure 160 and sealing structure 170 arranged on the fourth cladding layer 150.

The sealing structure 170 may be provided along an edge of the hollow structure 160. On the one hand, as the structural strength of the surface coil 100 may be affected due to an arrangement of the hollow structure 160, the sealing structure 170 may strengthen the structural strength of the surface coil 100, which allows the surface coil 100 to be provided with more hollow structures 160 without worrying about the structural strength of the surface coil 100 being greatly affected. On the other hand, the sealing structure 170 may seal and connect the arrangement layer 140 and the fourth cladding layer 150 at the hollow structure 160, ensuring that the coil assembly 130 is isolated from the external environment, so as to enable the coil assembly 130 to work safely and stably. Therefore, the radio frequency device 1000 in the present disclosure not only has good heat dissipation performance, but also has high structural strength, and may also operate safely and stably.

As shown in FIG. 19 and FIG. 20, the sealing structure 170 may include a sealing portion 171, a bonding region 172, and a stitching portion 173. The bonding region 172 may surround the edge of the hollow structure 160 and bond the fourth cladding layer 150 and the arrangement layer 140. The bonding region 172 may be an annular region through which the arrangement layer 140 is bonded to the fourth cladding layer 150. The bonding region 172 may be configured to bond a gap between the arrangement layer 140 and the fourth cladding layer 150 at the hollow structure 160. In addition, the region after bonding where the gap between the arrangement layer 140 and the fourth cladding layer 150 at the hollow structure 160 is located may provide a flatter region for subsequent processes (e.g., a stitching operation, a sealing operation, etc., as described below) by providing a more level operating region. The sealing portion 171 may be provided along an outside edge of the bonding region 172 and seal the fourth cladding layer 150 and the arrangement layer 140. The sealing portion 171 may be understood as a structure capable of sealing the gap between the arrangement layer 140 and the fourth cladding layer 150 at the hollow structure 160. By sealing the sealing portion 171 to the fourth cladding layer 150 and the arrangement layer 140, the sealing portion 171 may completely seal the gap between the arrangement layer 140 and the fourth cladding layer 150 at the hollow structure 160. Sealing the sealing portion 171 to the fourth cladding layer 150 and the arrangement layer 140 may also further connect and fix the arrangement layer 140 and the fourth cladding layer 150 on the inner edge of the bonding region 172, ensuring the stability of the bonding region 172. The stitching portion 173 may be provided along an outer edge of the bonding region 172 and stitch the fourth cladding layer 150 and the arrangement layer 140. The stitching portion 173 may be understood as a structure formed by stitching the arrangement layer 140 with the fourth cladding layer 150 with a thread along the outer edge of the bonding region 172. The stitching portion 173 may have an effect of further tightening the connection between the fourth cladding layer 150 and the arrangement layer 140. Additionally, since the surface coil 100 is usually bent when using, the adhesive force and the structural strength of the bonding region 172 may be worse, and the thread of the stitching portion 173 provided along the outer edge of the bonding region 172 may share the force generated by the pulling of the fourth cladding layer 150 during the bending of the surface coil 100, ensuring stable bonding of a bonding layer. As used herein, the inner edge refers to an edge with the smallest perimeter among the edges of the bonding region 172, and the outer edge refers to an edge with the largest perimeter among the edges of the bonding region 172.

As shown in FIG. 18, the coil assembly 130 may include one or more coil units 131. When the coil assembly 130 includes a plurality of coil units 131, the plurality of coil units 131 may be arranged in an array. The plurality of coil units 131 may be arranged in a rectangular array (e.g., a rectangular array of m*n, where one of m and n is an integer greater than 0 and the other one of m and n is an integer greater than 1), a circular array, etc. The plurality of coils arranged in the array may be located substantially in the same plane (on which the arrangement layer 140 is located), the axes of the coil units 131 may be parallel and the axis of each of the coil units 131 may be perpendicular to the plane. In some embodiments, at least two coil units of the plurality of coil units 131 may be partially overlapped to achieve decoupling between the plurality of coil units 131. In some embodiments, the plurality of coil units 131 may be arranged at intervals, and each of the plurality of coil units 131 may be connected with a capacitive component or an inductive component to realize decoupling among the plurality of coil units 131 by the capacitive component or the inductive component.

As shown in FIG. 20, a first hole 161 is provided on the arrangement layer 140, and second holes 162 are provided on a position corresponding to the first hole 161 on the fourth cladding layer 150. The first hole 161 and the second holes 162 corresponding thereto may together form the hollow structure 160. Positions setting of the second holes 162 corresponding to the first hole 161 may be understood as, on the surface coil 100, the position of the first hole 161 may be coincide with a position of a corresponding second hole 162, so that the hollow structure 160 may penetrate the surface coil 100 along the thickness direction of the surface coil 100 (i.e., the Z direction in FIG. 17). The sealing structure 170 may be arranged along the edge of the first hole 161 and along the edge of the second hole 162. The bonding region 172 of the sealing structure 170 may surround the edge of the first hole 161 and the edge of the second hole 162 and bond the fourth cladding layer 150 and the arrangement layer 140. In addition, it should be noted that the hollow structure 160 may be a shape, such as circular, oval, polygonal, irregularly shaped, etc. In some embodiments, the bonding region 172 may be in a shape of a ring. The specific shape of the bonding region 172 may match the hollow structure 160. For example, when the hollow structure 160 is circular, the bonding region 172 may be circular. As another example, when the hollow structure 160 is oval, the bonding region 172 may be elliptical circular.

In some embodiments, as shown in FIG. 20, the fourth cladding layer 150 may include a top layer 151 and a bottom layer 152. The top layer 151 and the bottom layer 152 may be provided on a top surface and a bottom surface, respectively, of the arrangement layer 140, and at least one of the first coil assembly 110 and the second coil assembly 120 may be provided on the top surface of the arrangement layer 140. The edge of the top layer 151 and the bottom layer 152 may be glued or sewn together to clad the arrangement layer 140 and the coil assembly 130, thereby better protecting the coil assembly 130. In some embodiments, an edge of the arrangement layer 140, an edge of the top layer 151, and an edge of the bottom layer 152 may be bonded or stitched together to fix the fourth cladding layer 150 in place relative to the arrangement layer 140.

In some embodiments, the second holes 162 may be provided on both the top layer 151 and the bottom layer 152 at corresponding positions. The second holes 162 provided on both the top layer 151 and the bottom layer 152 at corresponding positions may be understood that for any second hole 162 on the top layer 151, there may be a corresponding second hole 162 provided on the bottom layer 152. The second holes 162 on the top layer 151 and the bottom layer 152 on the surface coil 100 may overlap to cooperate with the first hole 161, and the hollow structure 160 may penetrate the surface coil 100 along the thickness direction of the surface coil 100 (i.e., the Z direction). The sealing structure 170 may be provided along the edge of the first hole 161, the edge of the second hole 162 on the top layer 151, and the edge of the second hole 162 on the bottom layer 152. The sealing structure 170 may connect the top layer 151, the bottom layer 152, and the arrangement layer 140 at the edge of the hollow structure 160 and seal a gap between the arrangement layer 140 and the top layer 151 at the hollow structure 160 and a gap between the arrangement layer 140 and the top layer 151 at the hollow structure 160.

In some embodiments, a flexible filler 180 may be provided between the arrangement layer 140 and the top layer 151 as shown in FIG. 20. Since the flexible filler 180 is soft, on the one hand, the flexible filler 180 may protect the coil assembly 130, and on the other hand, the surface coil 100 provided with the flexible filler 180 may enhance human comfort when contact with the human body (e.g., when wrapping an area of the body to be scanned). In some embodiments, the flexible filler 180 may include felt. The felt may further act as a fireproofing and thermal insulator. In some embodiments, the flexible filter 180 may include a material that does not interfere with the imaging of a magnetic resonance device using the radio frequency device 1000, such as cotton, feathers, polyester fibers, etc. In some embodiments, the flexible filler 180 may not be provided between a portion of the fourth cladding layer 150 in the bonding region 172 (including the top layer 151 and the bottom layer 152) and the arrangement layer 140 to make the connection between the fourth cladding layer 150 and the arrangement layer 140 more stable. In other embodiments, the flexible filler 180 may be provided between the portion of the fourth cladding layer 150 in the bonding region 172 (including the top layer 151 and the bottom layer 152) and the arrangement layer 140. The amount of the flexible filler 180 may be reduced from the outer edge of the bonding region 172 toward the inner edge of the bonding region 172 to allow for a slope between an outer edge of the bonding region 172 and the inner edge, allowing for a gentle transition between the sealing structure 170 and a structure outside the sealing structure 170.

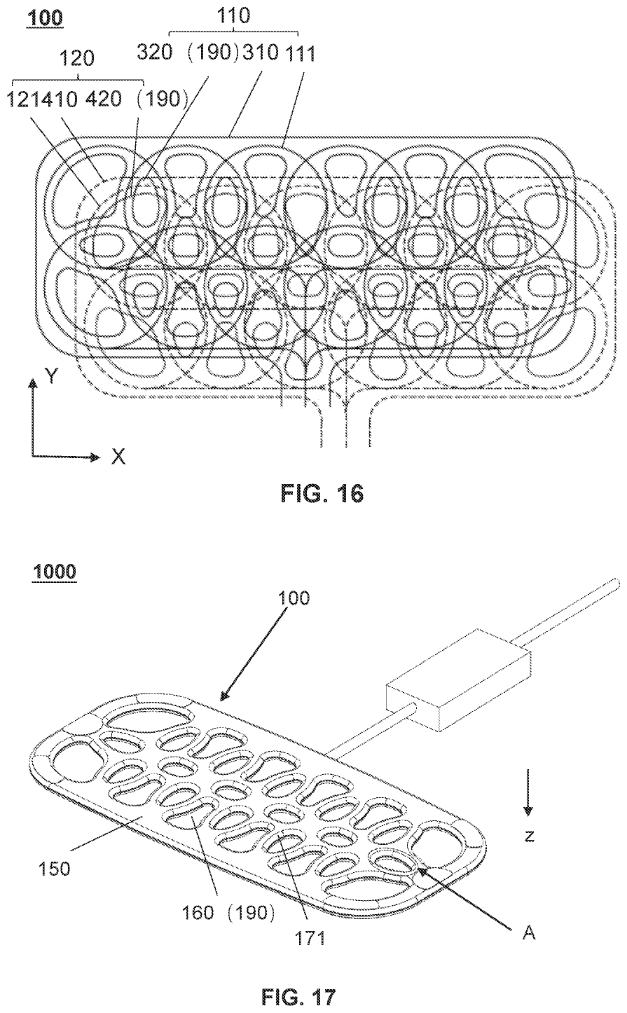

FIG. 21 is a diagram illustrating a cross-sectional view of a partial region of a radio frequency device according to some embodiments of the present disclosure. In some embodiments, as shown in FIG. 21, the bottom layer 152 may include an annular region 153 formed around the sealing structure 170. In the annular region 153, a distance d between the bottom layer 152 and the arrangement layer 140 in the thickness direction of the surface coil 100 may decrease from an outer side of the annular region 153 toward an inner side of the annular region 153. When the surface coil 100 is provided on a body surface of a subject to be scanned, a portion of the surface coil 100 that contacts the body surface may be smoothly lifted (in a direction away from the body surface) due to the arrangement of the sealing structure 170 and the flexible filler 180. The annular region 153 may be formed on the bottom layer 152, which may effectively reduce a contact area between the surface coil 100 and the body surface of the subject to be scanned and increase the surface area on the bottom layer 152 for heat dissipation. After setting the annular region 153, the actual surface area for heat dissipation on the bottom layer 152 may be much larger than an area of the second hole 162.

In some embodiments, a annular region in an annular shape may be formed on the top layer 151 similar to the annular region 153 on the bottom layer 152. The annular region 153 on the top layer 151 and the annular region 153 on the bottom layer 152 may be structured and arranged in a similar manner. In some application scenarios, the top layer 151 may contact the body surface of the subject to be scanned, which may also have a better heat dissipation performance.

In some embodiments, there may be a plurality of hollow structures 160, and there may be a plurality of sealing structures 170. The plurality of sealing structures 170 may be provided in one-to-one correspondence with the plurality of hollow structures 160. The plurality of sealing structures 170 may be provided in one-to-one correspondence with the plurality of hollow structures 160, which may be understood that the count of sealing structures 170 is the same as the count of hollow structures 160, and an edge of each of the plurality of hollow structures 160 may be provided correspondingly with the sealing structure 170. By providing the plurality of hollow structures 160, it may be possible to enable the surface coil 100 to better dissipate heat.

In some embodiments, the fourth cladding layer 150 may include leather. In some embodiments, the leather may be polyurethane leather (i.e., PU leather). The sealing portion 171 may include an oiled edge structure. The leather material may have the advantages of being lightweight, aging-resistant, abrasion-resistant, easy to bend, etc. The fourth cladding layer 150 may also include other materials that do not interfere with the imaging of the magnetic resonance device using the radio frequency device 1000, such as polyester fabric.

The material of the arrangement layer 140 may be similar to the material of the fourth cladding layer 150 described above. In some embodiments, the arrangement layer 140 and the fourth cladding layer 150 may include the same material. For example, the arrangement layer 140 and the fourth cladding layer 150 may both include leather. In other embodiments, the arrangement layer 140 and the fourth cladding layer 150 may include different materials. For example, the arrangement layer 140 may include polyester fabric and the fourth cladding layer 150 may include leather.

In some embodiments, the sealing structure may be formed by using a sealant applied at edges of the hollow structure 160 (including the first hole 161 and the second hole 162). In some embodiments, the sealing portion 171 may include an oiled edge structure when the fourth cladding layer 150 includes leather. The oiled edge structure may be formed by applying a leather sealing oil to an edge of the leather. By setting the leather material and the oiled edge structure, the oiled edge structure may have a very good sealing performance as well as increasing the structural strength of the surface coil 100 while ensuring that the fourth cladding layer 150 may have the above advantages of the leather material.

In some embodiments, the bonding region 172 may be formed by applying a glue between the arrangement layer 140 and the fourth cladding layer 150. In some embodiments, the bonding region 172 may be a heat press bonding region. The heat press bonding region is a structure formed by pasting or coating a heat press adhesive film between the arrangement layer 140 and the fourth cladding layer 150 and performing a heat pressing operation on the arrangement layer 140 and the fourth cladding layer 150. The formation of the heat press bonding region by the heat press process may make the bonding between the arrangement layer 140 and the adhesive layer more stable and a gap between the arrangement layer 140 and the adhesive layer may be substantially sealed.

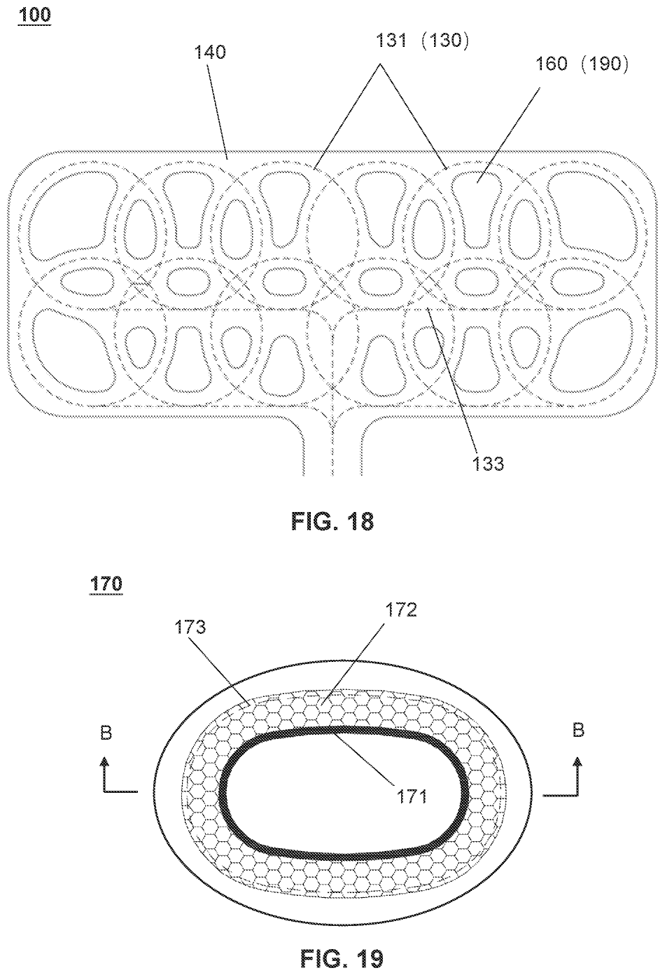

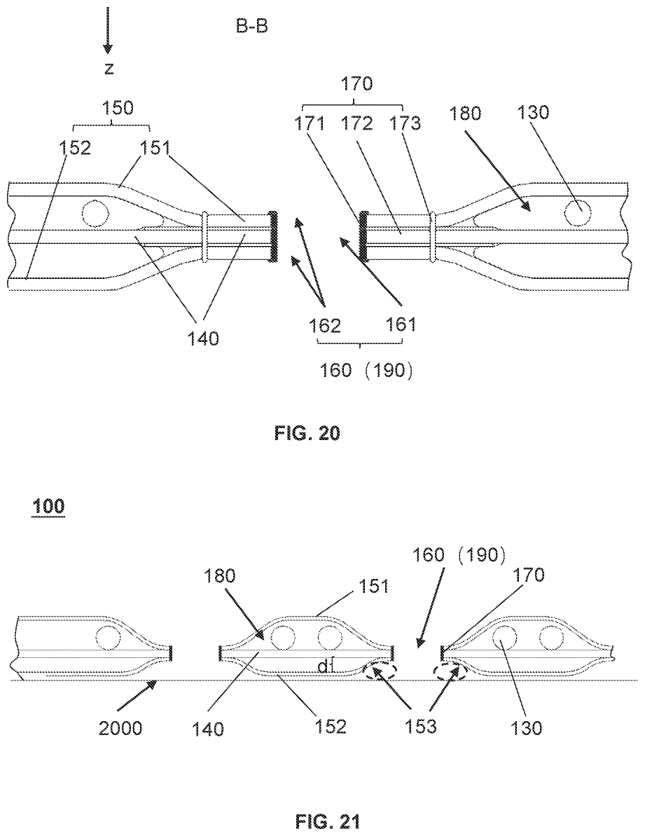

FIG. 22 is a schematic diagram illustrating an exemplary stacked configuration of a first coil assembly and a second coil assembly of a radio frequency device according to some other embodiments of the present disclosure. FIG. 23 is a diagram illustrating a cross-sectional view of a partial region of a radio frequency device according to some other embodiments of the present disclosure. In some embodiments, as shown in FIG. 22, the surface coil 100 may include a second surface coil 300 and a third surface coil 400. A first coil assembly 110 may be provided on the second surface coil 300, a second coil assembly 120 may be provided on the third surface coil 400, and the second surface coil 300 may be detachably connected with the third surface coil 400. FIG. 23 shows a cross-sectional view of a partial region of the radio frequency device in FIG. 22. As shown in FIG. 23, at least one hollow structure 160 of the second surface coil 300 may partially overlap with at least one hollow structure 160 of the third surface coil 400. For example, region E in FIG. 23 is a region in which the hollow structure 160 of the second surface coil 300 partially overlaps the hollow structure 160 of the third surface coil 400. Even after the second surface coil 300 and the third surface coil 400 are arranged in a stacked configuration as described above, it may be ensured that the at least one hollow structure 160 of the second surface coil 300 partially overlaps with the at least one hollow structure 160 of the third surface coil 400, which ensures the heat dissipation effect of the radio frequency device 1000.

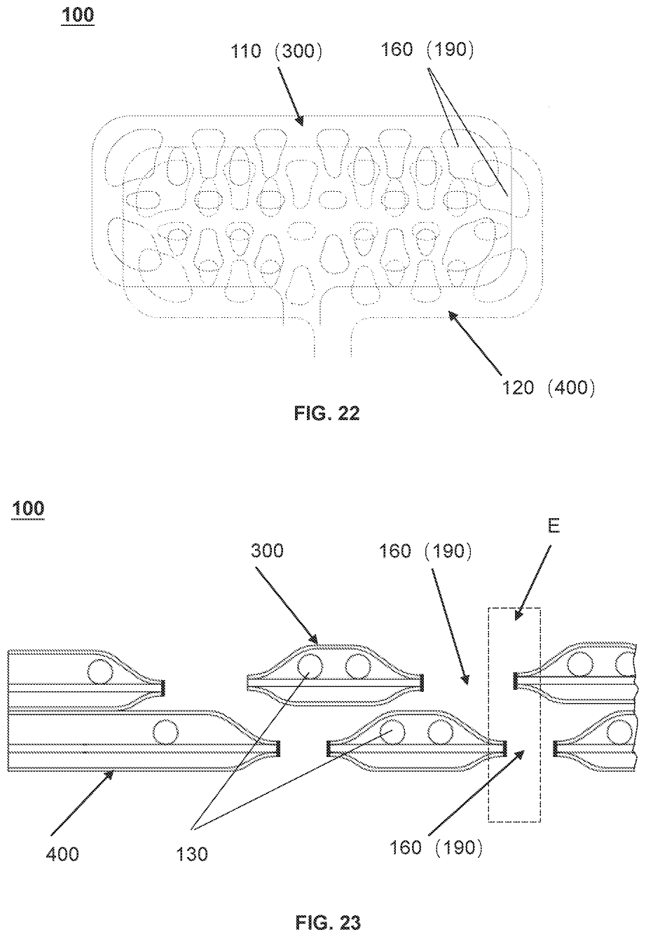

FIG. 24 is a schematic diagram illustrating an exemplary circuit structure of a surface coil according to some embodiments of the present disclosure. In some embodiments, as shown in FIG. 24, the surface coil 100 may include a transmission line 133 and a preamplifier 134. The coil assembly 130 may include a first coil assembly 110 and a second coil assembly 120 as described elsewhere in the present disclosure. The preamplifier 134 may be provided separately from the coil assembly 130. That is, the preamplifier 134 may be located outside the coil assembly 130 of the surface coil 100. A first coil unit in the first coil assembly 110 and/or a second coil unit in the second coil assembly 120 may be formed by a flexible conductive wire 132. The flexible conductive wire 132 may be a coaxial wire, a microstrip wire, or a twisted pair wire, etc. The flexible conductive wire 132 may surround to form at least one coil unit (the first coil unit 111 and/or the second coil unit 121) for receiving a magnetic resonance signal. The flexible conductive wire 132 may include a transmission segment 132-3 for tuning. The transmission line 133 may be configured to realize an impedance matching between the preamplifier 134 and the first coil unit 111 and/or the second coil unit 121. The preamplifier 134 may be configured to amplify the magnetic resonance signal received by the coil assembly 130. One end of the transmission line 133 may be connected with an output end of the flexible conductive wire 132, and another end of the transmission line 133 may extend outside of the coil assembly 130 and be connected with the preamplifier 134. On the one hand, the transmission line 133 may enable the impedance matching between the coil unit and the preamplifier 134 to enable the coil unit to be in a resonant state for receiving the magnetic resonance signals. On the other hand, the transmission line 133 may enable transmission of the magnetic resonance signal received by the coil assembly 130 (the coil unit) to the outside of the coil assembly 130. Compared to conventional coil arrays soldered to a PCB board where the conductors in the PCB boards are prone to generate induced currents as the changing currents in the imaging region, which may generate an eddy current affecting imaging in the imaging region, whereas the surface coil provided in the present disclosure may reduce the possibility of generating the eddy current and improve the imaging quality.

The flexible conductive wire 132 may be a pliable and stretchable wire. The flexible conductive wire 132 may be an electrically conductive elastomer obtained in the form of an electrically conductive filament. In some embodiments, the coil units may be formed by cutting the conductive filaments and crimping the conductive filaments. Additionally, an outer layer of the electrically conductive filament may be wrapped by a constraining layer. In some embodiments, the constraining layer may be insulating.

In some embodiments, the length of the transmission line 133 may be an odd multiple of one-quarter wavelength of a signal transmitted in the transmission line 133 to realize the impedance matching between the coil unit and the preamplifier 134. In some embodiments, the flexible conductive wire 132 may include a core wire 132-1 and a ground wire 132-2. The core wire 132-1 may be configured for the transmission of a signal, and the ground wire 132-2 may be configured to ground. The output end of the flexible conductive wire 132 may be located at one end of the core wire 132-1. In some embodiments, the transmission segment 132-3 may include a first transmission segment 132-3 used as an equivalent capacitor. In other embodiments, the transmission segment 132-3 may include a second transmission segment 132-3 used as an equivalent inductor. The first transmission segment 132-3 and/or the second transmission segment 132-3 may be equivalently a capacitive component or an inductive component to enable tuning of the coil assembly 130. The first transmission segment 132-3 may be equivalent as the capacitive component when the core wire 132-1 within the first transmission segment 132-3 is conducted and the ground wire 132-2 within the first transmission segment 132-3 is disconnected. The second transmission segment 132-3 may be equivalent as the inductive component when the core wire 132-1 within the second transmission segment 132-3 is disconnected and the ground wire 132-2 within the second transmission segment 132-3 is conducted. By arranging the transmission segment 132-3 for tuning and the transmission line 133 for impedance matching, there is no longer a need to arrange the capacitive component or the inductive component on the radio frequency device 1000, which may make it possible that the surface coil 100 may have more space for providing more hollow structures 160 to enable better heat dissipation of the radio frequency device 1000.

The coil assembly 130 may be configured to receive a radio frequency signal. The coil assembly 130 may receive the radio frequency signal in a preset frequency range by sensing radiation of electromagnetic waves within the preset frequency range. In some embodiments, the coil assembly 130 may be affixed to human tissue to receive a magnetic resonance signal from the human tissue.

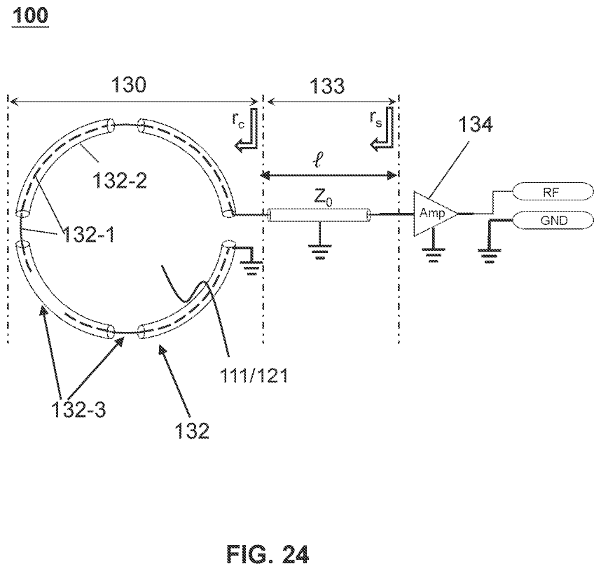

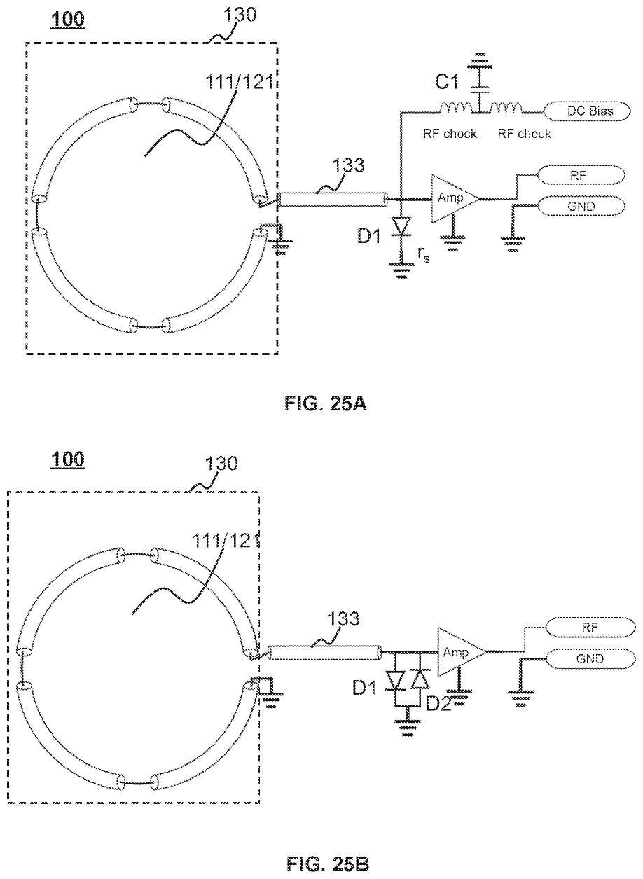

In some embodiments, the transmission line 133 may transmit the magnetic resonance signal to the preamplifier 134, and the preamplifier 134 may provide gain to the magnetic resonance signal to amplify the magnetic resonance signal. As shown in FIG. 25A and FIG. 25B, the preamplifier Amp may be provided on an output end of the transmission line 133.

In some embodiments, the surface coil 100 may further include a transmission component, which may be connected with the output end of the preamplifier 134 for transmitting the magnetic resonance signal to an imaging body or other device. In some embodiments, as shown in FIG. 24, the transmission component may include a radio frequency component RF, and the signal output end of the preamplifier Amp may output the magnetic resonance signal through an end of the radio frequency component RF. In some embodiments, the radio frequency component RF may include a communication component such as an antenna, a radio frequency front end, a radio frequency transceiver module, a baseband signal processor, etc. In some embodiments, the transmission component may include a plug-in connector, and the coil assembly 130 may transmit the magnetic resonance signal to the imaging body through the plug-in connector.

In some embodiments, the flexible conductive wire 132 in the coil assembly 130 may be enwound to form one or more coil units (the first coil unit 111 and/or the second coil unit 121). The one or more coil units (the first coil unit 111 and/or the second coil unit 121) may receive the MR signal by electromagnetic induction and output the MR signal to other components or equipment (e.g., the preamplifier 134, etc.). Compared to a conventional coil array set within a PCB board, the coil assembly 130 in the present disclosure may fit more closely to the human body, which improves a signal-to-noise ratio of the received magnetic resonance signal. In some embodiments, the flexible conductive wire 132 may include a coaxial wire, a microstrip wire, or other composite flexible conductive wires having a plurality of conductors (e.g., the core wire and the ground wire).

In some embodiments, the transmission segment 132-3 may be a segment in the flexible conductive wire 132, and the coil unit (the first coil units 111 and/or the second coil unit 121) may include one or more transmission segments 132-3. In some embodiments, the transmission segment 132-3 may hold or release charges while receiving the magnetic resonance signals by means of a connection. That is, an outer layer of the transmission segment 132-3 in the flexible conductive wire 132 may be provided with an opening/interval, which may be equivalent as a component such as an inductor or a capacitor, so that a resonance frequency of the coil assembly 130 may be close to a frequency of the magnetic resonance signal to produce a magnetic resonance phenomenon, thereby realizing the tuning of the coil assembly 130. The flexible conductive wire 132 may include a coaxial wire. The flexible conductive wire 132 may include an inner core layer and a shield layer provided outside the inner core layer. The inner core layer may be continuously enwound without interruptions, and the shield layer may be enwound with interruptions. In this embodiment, the interruptions in the shield layer may have an effect of tuning capacitance. The inner core layer and the shield layer may be filled with a dielectric material, and the inner core layer and the shield may be matched to realize the resonance of the flexible conductive wire 132. More specifically, the shield layer at a port of the flexible conductive wire 132 may be grounded, and the inner core layer at the port of the flexible conductive wire 132 may be directly connected with a core wire of a coaxial transmission line of a transmission cable.

In some embodiments, the flexible conductive wire 132 may include a core wire and a ground wire, and the output end of the flexible conductive wire 132 may be an end of the core wire. The transmission segment 132-3 may include a first transmission segment used as an equivalent capacitor and/or a second transmission segment used as an equivalent inductor. The core wire within the first transmission segment may be conducted and the ground wire within the first transmission segment may be disconnected. The core wire within the second transmission segment may be disconnected and the ground wire within the second transmission segment may be conducted.

In some embodiments, the core wire may be a wire that transmits electrical energy, and the ground wire may be a wire that has zero potential to ground. In some embodiments, the output end of the flexible conductive wire 132 may be arranged on one end of the core wire so as to output the received magnetic resonance signal. The transmission segment 132-3 may hold and release charge through the conductivity and disconnectivity of the core wire and the ground wire. Exemplarily, when the core wire within the first transmission segment is conducted and the ground wire within the first transmission segment is disconnected, alternating current may pass through the first transmission segment and direct current may be blocked by the first transmission segment, thereby the first transmission segment being equivalent to the capacitor. When the core wire within the second transmission segment is disconnected and the ground wire within the second transmission segment is connected, direct current may pass through the second transmission segment and alternating current may be blocked by the second transmission segment, thereby the second transmission segment being equivalent to an inductor.

One end of the transmission line 133 may be connected with the output end of the flexible conductive wire 132, and the other end of the transmission line 133 may extend outside of the coil assembly 130 and be connected with the preamplifier 134. If the load includes the preamplifier, an input impedance before the signal input of the preamplifier 134 may be rₛ. In some embodiments, a relationship between the input impedance rₛ located before the signal input of the preamplifier 134, the length [symbol] of the transmission line 133, and a characteristic impedance z₀ of the transmission line 133 may be denoted by the following equation (1):

$${r}_{s} = {Z}_{0} \frac{{r}_{c} + {jZ}_{0} tan \frac{2 π}{λ} ℓ}{{Z}_{0} + {jr}_{c} tan \frac{2 π}{λ} ℓ} \qquad ( 1 )$$

rₛ denotes the input impedance located before the signal input of the preamplifier 134, r_{c} denotes the input impedance of the coil assembly 130, [symbol] denotes the length of the transmission line 133, z₀ denotes the characteristic impedance of the transmission line 133, and λ denotes the wavelength of the magnetic resonance signal. In some embodiments, where the length of the transmission line 133 is an odd multiple of ¼ wavelength λ, the relationship between the input impedance rₛ located before the signal input of the preamplifier 134, the length [symbol] of the transmission line 133, and a characteristic impedance z₀ of the transmission line 133 may be denoted by the equation (2) as follows:

$${r}_{s} = \frac{{Z}_{0}^{2}}{{r}_{c}} \qquad ( 2 )$$

According to the above equation (2), it may be noted that when the length of the transmission line 133 is an odd multiple of ¼ wavelength λ, the characteristic impedance z₀ of the transmission line 133 may be a geometrical mean of the input impedance rₛ located before the signal input terminal of the preamplifier 134 and the input impedance r_{c} of the coil assembly 130. That is, a real part of the input impedance rₛ located before the signal input terminal of the preamplifier 134 and the real part of the input impedance r_{c} of the coil assembly 130 are equal and an imaginary part of the input impedance rₛ and an imaginary part of the real part of the input impedance r_{c} are opposite, so as to realize an impedance transformation (also referred to as the impedance matching) between the coil unit 111 or the coil unit 121 and the preamplifier 134.

In the embodiments of the present disclosure, the impedance matching of the circuit may be achieved by the design of the flexible transmission line 133, and picking of the surface coil may be achieved by a portion (e.g., a transmission segment) of the flexible conductive wire 132 of the surface coil, such that the surface coil 100 need not be provided with an additional rigid discrete radio frequency device (e.g., PCB boards and electronic components used to perform tuning and impedance matching). Thus, the surface coil is ensured to be flexible so as to have a better fit with a body surface of an imaging target. Further, extrusion and deformation of human tissues that are fitted with the surface coil may be avoided, thereby reducing the deformation of a radio frequency field (B1 field) and improving the accuracy of magnetic resonance imaging. Furthermore, the surface coil provided by the embodiments of the present disclosure may be more closely fitted with curved surface region (e.g., the thyroid and the carotid artery region) of the human body, which is more conducive to the imaging of a curved anatomical structure in the magnetic resonance application.

FIG. 25A is a schematic diagram illustrating an exemplary detuning process of a surface coil according to some embodiments of the present disclosure. As shown in FIG. 25A, the surface coil 100 may include a diode D1 and a direct current bias DC Bias (i.e., a voltage source). The direct current bias DC Bias may be coupled to a positive pole of the diode D1. The positive pole of the diode D1 may also be coupled to a signal output end of the transmission line 133 and a signal input end of the preamplifier Amp, and a negative pole of the diode D1 may be grounded. When the direct current bias DC Bias powers in reverse, the direct current bias DC Bias may provide a negative voltage, causing the diode D1 to be in a cut-off-state that is equivalent to an open circuit, and the coil assembly 130 may be in a tuned state to output the magnetic resonance signal. Correspondingly, the preamplifier Amp may receive the magnetic resonance signal. When the direct current bias DC Bias powers in a positive direction, the direct current bias DC Bias may provide a positive voltage so that the diode D1 may be in an on-state that is equivalent to a short circuit. The output end of the coil assembly 130 may be equivalent to a large impedance (e.g., impedance z₀²/0, where z₀ is the characteristic impedance of the transmission line 133), which is close to a broken circuit, and the coil assembly 130 may be in a detuned state and may not output the magnetic resonance signal. Correspondingly, the preamplifier Amp may not receive the magnetic resonance signal.

Embodiments provided in the present disclosure may drive a diode (e.g., diode D1) to be switched off or conducted by controlling a power supply direction of a voltage source (e.g., the direct current bias DC Bias) to realize switching and controlling the tuned state and the detuned state of the coil assembly 130, thereby modulating the magnetic resonance signal output by the coil assembly 130.

In some embodiments, the direct current bias DC Bias may be coupled to the diode D1 via two radio frequency chokes (RF chocks) as shown in FIG. 25A and the RF chocks may be used to suppress high frequency noise in the circuit. In some embodiments, the two RF chocks may also be grounded in-between via capacitor C1, and the capacitor C1 may be used to filter out noise and fluctuations in the circuit.

FIG. 25B is a schematic diagram illustrating an exemplary passively detuned surface coil according to some embodiments of the present disclosure. In some embodiments, the surface coil 100 may include a diode D1 and a diode D2, as shown in FIG. 25B. A positive pole of the diode D1 may be connected with a signal output end of the transmission line 133 and a signal input end of the preamplifier Amp. A negative pole of the diode D1 may be grounded. The positive pole of the diode D2 may be grounded, and the negative pole of diode D2 may be connected with the positive pole of diode D1. In some embodiments, diode D2 may act as a passive diode for diode D1 to allow the coil assembly 130 to make a switch between a passive detuned state or a tuned state. As the coil assembly 130 may generate a high-power electromagnetic field during a signal excitation phase, the electromagnetic field may cause a large voltage and/or current to be generated at the output end of the coil assembly 130, causing the conduction of diode D2, driving the conduction of diode D1, which is equivalent to a short circuit. So, the output end of the coil assembly 130 may be equivalent to a large impedance close to a broken circuit, and the coil assembly 130 may be in the passive detuned state and may not output a magnetic resonance signal. Correspondingly, the coil assembly 130 may not generate the electromagnetic field in a signal-receiving phase, the diode D1 and the diode D2 may be in an off state, which is equivalent to an open circuit, and the coil assembly 130 may be in a tuned state to output the magnetic resonance signal.

In the embodiments of the present disclosure, two diodes (e.g., the diode D1 and the diode D2) may be switched off or conducted during the signal-receiving phase and the signal excitation phase, to realize switching and controlling the tuned state and the detuned state of the coil assembly 130, thereby modulating the magnetic resonance signal output by the coil assembly 130. Furthermore, the surface coil 100 provided in the present disclosure may avoid tuning and detuning in an imaging range, which reduces a risk of heating of the human body tissues that are affixed to the surface coil 100 and improves the safety of the radio frequency device.

In some embodiments, channel noise information of the first coil assembly and channel noise information of the second coil assembly may be obtained during calibration or scanning. By analyzing the channel noise information, a coupling relationship between channels of the first coil assembly or the second coil assembly and information about a noise-matching status of each of the channels may be obtained. The coupling relationship between the channels of the first coil assembly or the second coil assembly may usually be expressed as a square matrix, where values at the non-diagonal (also referred to as a non-diagonal value) in the matrix may be a coupling state between the channels, and values at the diagonals (also referred to as a diagonal value) in the matrix may be loading information (the noise-matching status) for each of the channels. When the channels overlap too much, values at the non-diagonal of the noise matrix may be higher, which reflects an unconventional inter-channel coupling relationship. The values at the diagonal p of the matrix may directly reflect the noise-matching status of the coil, and when a channel in the coil is elevated, o a load associated with the channel may change, the value of the channel at the diagonal of the matrix may also have a different performance from a normal level.

In the embodiment of the present disclosure, a range of the non-diagonal value and the diagonal value in the noise matrix of the coils may be determined, and a suitable threshold may be set. Then, channels that overlaps too much may be determined based on the non-diagonal values of the noise matrix. In the above manner, coil units of the first coil assembly that are needed to be opened and coil units of the second coil assembly that are needed to be turned off may be determined, or coil units of the first coil assembly that are needed to be turned off and coil units of the second coil assembly that are needed to be opened may be determined.

After determining a pair of channels that overlap too much, channels that are far from a test region may be further determined, and then the channels that are far from a test region may be detuned. The channels that are far from a test region may be determined based on the change of the diagonal values in the noise matrix. For example, compared to the previously set threshold (which needs to turn off one of the phase couplings), a channel that is farther away from the test region has a large change in the diagonal value. After distinguishing between channels that need to be resonated or detuned in the above manner, the channels in the coil may be activated or deactivated to achieve a more efficient use of the coils for scanning.

In some embodiments, the radio frequency device may further include a channel selection controller, and the channel selection controller may perform channel selection of the coil units of the first coil assembly 110 and the second coil assembly 120 according to the following operations.

In operation S1, a plurality of sets of first noise data corresponding to a plurality of channels of the first coil assembly 110 and the second coil assembly 120 may be obtained.

In some embodiments, the channel selection controller may obtain a set of first noise data corresponding to each channel of the first coil assembly 110 and the second coil assembly 120, which are concatenated together and used for magnetic resonance scanning of a subject. In some embodiments, the channel selection controller may obtain and receive, in real time, the plurality of sets of first noise data corresponding to the plurality of channels of the first coil assembly 110 and the second coil assembly 120 during a calibration phase or a scanning phase of the magnetic resonance imaging device. The calibration phase refers to a process of setting scanning parameters for the magnetic resonance imaging device based on personalized information (e.g., a scanning portion or region) of the subject.

The channel selection controller may obtain the plurality of sets of first noise data corresponding to the plurality of channels by receiving coil acquisition signals at stages such as prior to, during, or after setting the scanning parameters for the magnetic resonance imaging device. The scanning phase refers to a process of performing a magnetic resonance scan on the subject.

The channel selection controller may complete positioning of a surface coil (the first coil assembly 110 and/or the second coil assembly 120) and may receive, before each radio frequency signal is excited during the process of performing the magnetic resonance scan on the subject, a signal acquired by a radio frequency coil, thereby obtaining the plurality of sets of first noise data collected by each channel.

In operation S2, a target noise matrix may be obtained based on the plurality of sets of first noise data.

The target noise matrix may reflect a coupling relationship between channels, wherein the diagonal values in the target noise matrix may reflect an autocorrelation characteristic of the channels, and the non-diagonal values may reflect a cross-correlation characteristic between the channels. In some embodiments, two sets of non-diagonal values located on both sides of the diagonal of the target noise matrix may be symmetrical to each other.

Further, the channel selection controller may determine the target noise matrix based on the first noise data via an algorithm. For example, the channel selection controller may obtain the target noise matrix by performing conjugate dot product on the plurality of sets of first noise data of the channels. As another example, the channel selection controller may obtain the target noise matrix by post-processing (e.g., normalizing) a constructed initial noise matrix (e.g., the matrix obtained by conjugate dot product).

As the target noise matrix is obtained by post-processing such as normalization of the initial noise matrix, the target noise matrix may be visualized, which makes it easy to analyze the noise data.

In operation S3, a target channel may be determined from the plurality of channels based on the target noise matrix and a location of a region of interest.

In order to avoid a situation where over-coupling may occur between the channels, the channel selection controller may determine the target channel from the plurality of channels based on the target noise matrix after determining the target noise matrix. The target channel may include a channel that is over coupled with one of the plurality of channels of the coil units.

Specifically, when there is too much overlap or over-coupling between the channels, the values in the non-diagonal regions of the target noise matrix may be higher, thereby reflecting an unconventional coupling relationship between the channels. Therefore, based on the target noise matrix, the channel selection controller may determine multiple channels corresponding to non-diagonal values that are greater than a first threshold as candidate channels, and then, based on diagonal values corresponding to the candidate channels in the target noise matrix, the target channel may be determined from the candidate channels. There may be over coupling between the determined candidate channels.

The channel selection controller may determine candidate channels with excessive overlap based on the target noise matrix and then determine the target channel from the candidate channels.

Further, since the values in the diagonal portion of the target noise matrix may reflect the noise-matching status of the surface coil, when a channel in the coil is elevated (e.g., channels above and below a peripheral coil are away from a scanning area after wrapping the scanning site due to excessive overlap), the value of the channel on the diagonal of the matrix may be abnormal in response to a change in load.

The channel selection controller may compare the non-diagonal values in the target noise matrix with the first threshold, which may help screen out abnormal channels, thereby determining two or more channels that exist over-coupling. Then, based on the target noise matrix, the channel selection controller may compare diagonal values corresponding to channels that exist over-coupling with a second threshold, which may help determine a channel that is closer to the scanning portion among two or more channels that overlap excessively. Thus, during a magnetic resonance scanning process, the channel selection controller may control the resonance of the target channel and control the detuning of the channel that exists over-coupling with the target channel, so that the target channel may be used for collecting the magnetic resonance signal when performing the magnetic resonance scanning process, thereby avoiding noise interference while improving accuracy of data acquisition.

It should be noted that the foregoing description regarding the radio frequency device is for exemplification and illustration only and does not limit the scope of the present disclosure. For those who skilled in the art, various corrections and changes may be made to the radio frequency device under the guidance of the present disclosure. However, these corrections and changes remain within the scope of the present disclosure.

The above radio frequency device 1000 of the present disclosure may be manufactured according to the following operations.

In operation S 11, the coil assembly 130 may be placed on the arrangement layer 140 and the fourth cladding layer 150 may be covered over the coil assembly 130.

In operation 12, the hollow structure 160 may be provided. Specifically, the one or more first holes 161 may be provided on the arrangement layer 140, and the one or more second holes 162 corresponding to positions of the first holes 161 may be provided on the fourth cladding layer 150.

In operation 13, the arrangement layer 140 and the fourth cladding layer 150 may be bonded together around the edge of the hollow structure 160 (e.g., the first holes 161 and the second holes 162) to form the bonding region 172. Specifically, a heat press adhesive film may be applied (or a heat press adhesive may be applied) in an annular region that surrounds the edge of the hollow structure 160, and the annular region may then be heat pressed. In other embodiments, an adhesive may be applied to the annular region surrounding the edge of the hollow structure 160.

In operation 14, stitching may be performed along an outer edge of the bonding region 172 to stitch the arrangement layer 140 and the fourth cladding layer 150 together. Specifically, a thread may be used to stitch the arrangement layer 140 and the fourth cladding layer 150 together at the outer edge of the bonding region 172.

In operation 15, sealing may be performed along an inner edge of the bonding region 172 to seal the arrangement layer 140 and the fourth cladding layer 150. In some embodiments, a sealant may be applied to the inner edge of the bonding region 172 (i.e., a location of the edge of the hollow structure 160). In some r embodiments, leather edge oil may be applied to the inner edge of the bonding region 172 (i.e., the location of the edge of the hollow structure 160) when the fourth cladding region 150 includes leather.

It should be noted that the order of the above operations is not fixed. The order of some of the operations may be adjusted during the process of manufacturing the radio frequency device 1000. For example, operation S12 may be performed first to provide the first hole 161 and the second hole 162 on the arrangement layer 140 and the fourth cladding layer 150, respectively. Then operation S11 may be performed to arrange the coil assembly 130 on the arrangement layer 140. As another example, operation S14 and operation S15 may be interchanged. As another example, one of operation S14 and operation S15 may be performed first, followed by operation S13, followed by the other one of operation S14 and operation S15.

In some embodiments of the present disclosure, a radio frequency device is also provided. The radio frequency device may include a surface coil 100. The surface coil 100 may include at least one coil assembly 130. The at least one coil assembly 130 may include a first coil assembly 110 and a second coil assembly 120. The first coil assembly 110 may include at least two first coil units 111 arranged in an array, and the second coil assembly 120 may include at least one second coil unit 112. The at least one second coil unit 112 and the at least two first coil unit 111 may be physically separated from each other and may be arranged staggered up and down.

In some embodiments of the present disclosure, a magnetic resonance device is also provided. The magnetic resonance device may include a radio frequency device 1000 as described elsewhere in the present disclosure. The magnetic resonance device, by using the radio frequency device 1000, may improve a depth signal-to-noise ratio, improve parallel imaging capability in the AP direction and the other encoding directions (e.g., an up-to-down direction, a right-to-left direction), and improve the uniformity of the synthesized signal-to-noise ratio or the signal distribution in the region of interest, which may further improve image quality.

It should be noted that the foregoing description is intended to be exemplary and illustrative only and does not limit the scope of the present disclosure. For those skilled in the art, various amendments and changes may be made under the guidance of the present disclosure. However, these amendments and changes remain within the scope of the present disclosure.

The embodiments of the present disclosure may include but are not limited to the following possible beneficial effects. (1) The size of the coil unit (e.g., the first coil unit and the second coil unit) can be determined based on a clinical need (e.g., relevant information about the region of interest) without being affected by the count of surface coil channels, which may improve a penetration depth of the signal-to-noise ratio of the surface coil. (2) The first coil assembly and the second coil assembly may be arranged in a stacked configuration, which may not only increase the scanning coverage area, but also accelerate the acquisition in the AP direction, which may improve the signal-to-noise ratio of a stacked region and the parallel imaging capability in the AP direction and other encoding directions (e.g., the up-down direction, the left-right direction) to further obtain images with better image quality in fast imaging in the AP direction. (3) The projection of the center of each second coil unit in the second coil assembly on the first coil assembly along the stacked direction may not correspond to the center of each first coil unit in the first coil assembly, or the projection of the center of the at least one second coil unit 121 on the first coil assembly 110 along the stacked direction may have a distance from the center of each of the at least two first coil units 111, which may make the signals of the first coil assembly and the second coil assembly complementary, improve the uniformity of the synthesized signal-to-noise ratio or the signal distribution in the region of interest, and further avoid uneven brightness of the image and improve uniformity of the image. Additionally, B1 field interference between a plurality of channels of the first coil assembly and the second coil assembly 120 may be reduced to minimize the B1 field interference, the signal-to-noise ratio and the parallel imaging capability in the AP direction and the other encoding directions (e.g., an up-to-down direction, a right-to-left direction) may be further improved, which may further improve the image quality. It should be noted that the beneficial effects that may be produced by different embodiments are different. The beneficial effects produced in different embodiments may be any one or a combination of any one or more of the above, or any other beneficial effect that may be obtained. (4) The second surface coil and the third surface coil may be detachably connected, which may enable the second surface coil and the third surface coil to be used independently as well as at the same time (e.g., in the stacked configuration), which may not only reduce cost, but also allow different combinations of the first coil assembly and the second coil assembly to be applied to a plurality of scanning scenarios with high image quality (e.g., with high signal-to-noise ratio and parallel imaging capability). (5) The surface coil of the radio frequency device may include an arrangement layer for arranging the coil assembly, a fourth cladding layer for cladding the coil assembly, and a sealing structure. The fourth cladding layer may form an outer skin for cladding the coil assembly. The hollow structure may be formed on the arrangement layer and the fourth cladding layer, and the hollow structure may facilitate heat dissipation of the radio frequency device when used. The sealing structure may, on the one hand, strengthen the structural strength of the surface coil, and on the other hand, may seal and connect the arrangement layer and the fourth cladding layer at the hollow structure to ensure that the coil assembly is isolated from the external environment, so as to enable the coil assembly to work safely and stably. Additionally, by setting up the transmission segment for tuning and the transmission line for impedance matching. It is no longer necessary to arrange the capacitive component or the inductive component on the radio frequency device, which may make it possible to set up more hollow structures on the surface coils with more space, allowing for better heat dissipation of the radio frequency device.

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the invention. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities or properties used to describe and claim certain embodiments of the present disclosure are to be understood as being modified in some instances by the term “about,” “approximate,” or “substantially.” For example, “about,” “approximate” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present specification) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A radio frequency device, comprising:
a surface coil, wherein the surface coil includes at least one coil assembly;
the at least one coil assembly including a first coil assembly and a second coil assembly, wherein
the first coil assembly includes at least two first coil units arranged in an array;
the second coil assembly includes at least one second coil unit; and
the first coil assembly and the second coil assembly are arranged in a stacked configuration.

2. The radio frequency device of claim 1, wherein
a projection of a center of each of the at least one second coil unit on the first coil assembly along a stacked direction has a distance from a center of each of the at least two first coil units.

3. The radio frequency device of claim 2, wherein
the projection of the center of each of the at least one second coil unit on the first coil assembly along the stacked direction is located between centers of adjacent first coil units of the at least two first coil units.

4. The radio frequency device of claim 3, wherein
the projection of the center of each of the at least one second coil unit on the first coil assembly along the stacked direction is located at a midpoint of a line connecting the centers of the adjacent first coil units.

5. The radio frequency device of claim 2, wherein
the at least two first coil units of the first coil assembly are partially overlapped to form one or more overlapped regions, and the projection of the center each of the at least one second coil unit on the first coil assembly along the stacked direction is located in one of the one or more overlapped regions.

6. The radio frequency device of claim 5, wherein
the projection of the center of each of the at least one second coil unit on the first coil assembly along the stacked direction is located at a center of the one of the one or more overlapped regions.

7. The radio frequency device of claim 5, wherein
the projection of the center of each of the at least one second coil unit on the first coil assembly along the stacked direction is located at a first overlapped region of adjacent first coil units arranged along a first direction;
the projection of the center of each of the at least one second coil unit on the first coil assembly along the stacked direction is located in a second overlapped region of the adjacent first coil units arranged along a second direction; and/or
at least four first coil units are arranged in an array along the first direction and the second direction of the adjacent first coil units, the four first coil units have a third overlapped region, and the projection of the center of each of the at least one second coil unit on the first coil assembly along the stacked direction is located in the third overlapped region.

8. The radio frequency device of claim 1, wherein
the second coil assembly includes at least two second coil units arranged in an array.

9. The radio frequency device of claim 1, wherein the surface coil has one or more through holes along a thickness direction of the surface coil.

10. The radio frequency device of claim 9, wherein the surface coil is configured to have a first surface coil, the first surface coil includes the first assembly and the second assembly;
the first surface coil further includes a first cladding layer,
the first coil assembly and the second coil assembly are both encased within the first cladding layer; and
the one or more through holes include a first hollow hole provided on the first cladding layer.

11. The radio frequency device of claim 9, wherein the surface coil is configured to have a second surface coil and a third surface coil, the second surface coil includes the first coil assembly, the third surface coil includes the second coil assembly; and
the second surface coil is detachably connected with the third surface coil.

12. The radio frequency device of claim 11, wherein
the second surface coil further includes a second cladding layer, the second cladding layer encases the first coil assembly;
the third surface coil further includes a third cladding layer, the third cladding layer encases the second coil assembly; and
the second cladding layer is detachably connected with the third cladding layer.

13. The radio frequency device of claim 12, wherein
the one or more through holes include a plurality of second hollow holes provided on the second cladding layer, and
a plurality of third hollow holes provided on the third cladding layer;
positions of the plurality of second hollow holes correspond to a position of a portion of the third cladding layer; and
positions of the plurality of third hollow holes correspond to a position of a portion of the second cladding layer.

14. The radio frequency device of claim 9, wherein the device further comprises an arrangement layer, a fourth cladding layer, and a sealing structure, the arrangement layer and the fourth cladding layer are flexible, at least one of the first coil assembly and the second coil assembly is provided on the arrangement layer, the fourth cladding layer is provided on the arrangement layer and covers the at least one of the first coil assembly and the second coil assembly;
the one or more through holes form a hollow structure;
the sealing structure is provided along an edge of the hollow structure; and
the sealing structure includes a sealing portion, a bonding region, and a stitching portion, wherein the bonding region wraps around outside the edge of the hollow structure and bonds the fourth cladding layer and the arrangement layer, the sealing portion is provided along an inner edge of the bonding region and is sealed to the fourth cladding layer and the arrangement layer, the stitching portion is provided along an outer edge of the bonding region and stitches the fourth cladding layer and the arrangement layer.

15. The radio frequency device of claim 14, wherein a first hole is provided in the arrangement layer;
one or more second holes are provided on the fourth cladding layer at a position corresponding to the first hole;
the sealing structure is provided along an edge of the first hole and an edge of the second hole;
the fourth cladding layer includes a top layer and a bottom layer, the top layer is provided on a top surface of the arrangement layer, the bottom layer is provided on a bottom surface of the arrangement layer, the at least one of the first coil assembly and the second coil assembly is provided on the top surface of the arrangement layer;
the one or more second holes are provided on the top layer and the bottom layer at corresponding positions, the sealing structure is provided along an edge of the first hole, an edge of the second hole on the top layer and an edge of the second hole on the bottom layer;
the bottom layer includes an annular region formed around the sealing structure; and
in the annular region, a distance between the bottom layer and the arrangement layer in the thickness direction of the surface coil decreases from an outer side of the annular region towards an inner side of the annular region.

16. The radio frequency device of claim 14, wherein the device further comprises an arrangement layer, a fourth cladding layer, and a plurality of sealing structures, the arrangement layer and the fourth cladding layer are flexible, the at least one coil assembly is provided on the arrangement layer, the fourth cladding layer is provided on the arrangement layer and covers the at least one coil assembly;
a plurality of hollow structures are formed through the surface coil along a thickness direction of the surface coil;
wherein the plurality of the sealing structures are provided in one-to-one correspondence with the plurality of hollow structures.

17. The radio frequency device of claim 16, the surface coil further including a transmission line and a preamplifier, wherein
the preamplifier is provided separately from the at least one coil assembly;
the at least one coil assembly includes a flexible conductive wire, the flexible conductive wire surrounds to form at least one coil unit for receiving a magnetic resonance signal;
the flexible conductive wire includes a transmission segment for tuning;
the transmission line is configured to realize an impedance matching between the coil unit and the preamplifier;
the preamplifier is configured to amplify the magnetic resonance signal received by the at least one coil assembly; and
one end of the transmission line is connected with an output end of the flexible conductive wire, and another end of the transmission line extends outside of the at least one coil assembly and is connected with the preamplifier.

18. The radio frequency device of claim 1, wherein the radio frequency device is applied in a magnetic resonance device.

19. A magnetic resonance device, comprising a surface coil, wherein the surface coil includes at least one coil assembly; and the at least one coil assembly includes a first coil assembly and a second coil assembly, wherein
the first coil assembly includes at least two first coil units arranged in an array;
the second coil assembly includes at least one second coil unit; and
the at least one second coil unit and the at least two first coil unit are physical separated from each other and are arranged staggered up and down.

20. A radio frequency device, comprising:
a first surface coil including at least one first coil assembly and a first cladding layer, the first cladding layer encasing the at least one first coil assembly;
a second surface coil including at least one second coil assembly and a second cladding layer, the second cladding layer encasing the at least one second coil assembly; and
wherein the first cladding layer is detachably connected with the second cladding layer.
